(19) United States
(12) Patent Application Publication
(10) Pub. No.: US 2016/0267971 A1
(43) Pub. Date: Sep. 15, 2016

(54) SEMICONDUCTOR MEMORY DEVICE

(71) Applicant: KABUSHIKI KAISHA TOSHIBA, Tokyo (JP)

(72) Inventor: Hiroshi MAEJIMA, Setagaya Tokyo (JP)

(21) Appl. No.: 15/055,284

(22) Filed: Feb. 26, 2016

(30) Foreign Application Priority Data
Mar. 10, 2015 (JP) 2015-047618

(51) Int. Cl. G11C 13/00

(52) U.S. Cl. CPC G11C 13/004

(57) ABSTRACT

A semiconductor memory device includes a first memory cell array electrically connected to a set of first bit lines, a second memory cell array electrically connected to a set of second bit lines, and a sense amplifier module that is physically located between the first and second memory cell arrays, and shared by the first and second memory cell arrays.

### CROSS-REFERENCE TO RELATED APPLICATION

This application is based upon and claims the benefit of priority from Japanese Patent Application No. 2015-047618, filed Mar. 10, 2015, the entire contents of which are incorporated herein by reference.

### FIELD

Embodiments described herein relate generally to a semiconductor memory device.

### BACKGROUND

A NAND-type flash memory in which memory cells are three-dimensionally arranged has been known.

### DESCRIPTION OF THE DRAWINGS

FIG. 1 is a block diagram illustrating a semiconductor memory device according to a first embodiment.

FIG. 2 is a block diagram illustrating memory cell arrays included in the semiconductor memory device according to the first embodiment.

FIG. 3 is a circuit diagram illustrating the memory cell arrays included in the semiconductor memory device according to the first embodiment.

FIG. 4 is a block diagram illustrating the semiconductor memory device according to the first embodiment.

FIG. 5 is a block diagram illustrating a sense amplifier and a data cache included in the semiconductor memory device according to the first embodiment.

FIG. 6 is a block diagram illustrating the sense amplifier and the data cache included in the semiconductor memory device according to the first embodiment.

FIG. 7 is a circuit diagram illustrating a sense amplifier and a bit line switching circuit included in the semiconductor memory device according to the first embodiment.

FIG. 8 is a circuit diagram illustrating the sense amplifier and the data cache included in the semiconductor memory device according to the first embodiment.

FIG. 9 is a sectional diagram illustrating the semiconductor memory device according to the first embodiment.

FIG. 10 is a sectional diagram illustrating memory cell arrays included in the semiconductor memory device according to the first embodiment.

FIG. 11 is a flowchart illustrating a data transferring method of the semiconductor memory device according to the first embodiment.

FIG. 12 is a timing diagram illustrating various signals acquired when the semiconductor memory device according to the first embodiment transfers data.

FIG. 13 is a circuit diagram illustrating the sense amplifier unit included in the semiconductor memory device according to the first embodiment.

FIG. 14 is a circuit diagram illustrating the sense amplifier unit included in the semiconductor memory device according to the first embodiment.

FIG. 15 is a schematic diagram illustrating the data transferring method of the semiconductor memory device according to the first embodiment.

FIG. 16 is a block diagram illustrating a semiconductor memory device according to a second embodiment.

FIG. 17 is a circuit diagram illustrating a sense amplifier and a bit line switching circuit included in the semiconductor memory device according to the second embodiment.

FIG. 18 is a circuit diagram illustrating the sense amplifier and a data cache included in the semiconductor memory device according to the second embodiment.

FIG. 19 is a sectional diagram illustrating the semiconductor memory device according to the second embodiment.

FIG. 20 is a block diagram illustrating a semiconductor memory device according to a third embodiment.

FIG. 21 is a block diagram illustrating a sense amplifier included in the semiconductor memory device according to the third embodiment.

FIG. 22 is a block diagram illustrating a semiconductor memory device according to a fourth embodiment.

FIG. 23 is a circuit diagram illustrating memory cell arrays included in the semiconductor memory device according to the fourth embodiment.

### DETAILED DESCRIPTION

Embodiments now will be described more fully hereinafter with reference to the accompanying drawings. In the drawings, the thickness of layers and regions may be exaggerated for clarity. Like numbers refer to like elements throughout. As used herein the term “and/or” includes any and all combinations of one or more of the associated listed items and may be abbreviated as “/”.

The terminology used herein is for the purpose of describing particular embodiments only and is not intended to be limiting of the invention. As used herein, the singular forms “a,” “an” and “the” are intended to include plural forms as well, unless the context clearly indicates otherwise. It will be further understood that the terms “comprises,” “comprising,” “having,” “includes,” “including” and/or variations thereof, when used in this specification, specify the presence of stated features, regions, steps, operations, elements, and/or components, but do not preclude the presence or addition of one or more other features, regions, steps, operations, elements, components, and/or groups thereof.

It will be understood that when an element such as a layer or region is referred to as being “on” or extending “onto” another element (and/or variations thereof), it may be directly on or extend directly onto the other element or intervening elements may also be present. In contrast, when an element is referred to as being “directly on” or extending “directly onto” another element (and/or variations thereof), there are no intervening elements present. It will also be understood that when an element is referred to as being “connected” or “coupled” to another element (and/or variations thereof), it may be directly connected or coupled to the other element or intervening elements may be present. In contrast, when an element is referred to as being “directly connected” or “directly coupled” to another element (and/or variations thereof), there are no intervening elements present.

It will be understood that, although the terms first, second, etc. may be used herein to describe various elements, components, regions, layers and/or sections, such elements, materials, regions, layers and/or sections should not be limited by these terms. These terms are only used to distinguish one element, material, region, layer or section from another element, material, region, layer or section. Thus, a first element, material, region, layer or section discussed below could be termed a second element, material, region, layer or section without departing from the teachings of the present invention.

Relative terms, such as “lower”, “back”, and “upper” may be used herein to describe one element's relationship to another element as illustrated in the Figures. It will be understood that relative terms are intended to encompass different orientations of the device in addition to the orientation depicted in the Figures. For example, when the structure in the Figure is turned over, elements described as being on the “backside” of substrate would then be oriented on “upper” surface of the substrate. The exemplary term “upper”, may therefore, encompasses both an orientation of “lower” and “upper,” depending on the particular orientation of the figure. Similarly, when the structure in one of the figures is turned over, elements described as “below” or “beneath” other elements would then be oriented “above” the other elements. The exemplary terms “below” or “beneath” may, therefore, encompass both an orientation of above and below.

Embodiments are described herein with reference to cross section and perspective illustrations that are schematic illustrations of the embodiments. As such, variations from the shapes of the illustrations as a result, for example, of manufacturing techniques and/or tolerances, are to be expected. Thus, embodiments should not be construed as limited to the particular shapes of regions illustrated herein but are to include deviations in shapes that result, for example, from manufacturing. For example, a region illustrated or described as flat may, typically, have rough and/or nonlinear features. Moreover, sharp angles that are illustrated, typically, may be rounded. Thus, the regions illustrated in the figures are schematic in nature and their shapes are not intended to illustrate the precise shape of a region and are not intended to limit the scope of the present invention.

Embodiments provide a semiconductor memory device which is capable of performing a high-speed operation.

In general, according to an embodiment, a semiconductor memory device includes a first memory cell array electrically connected to a set of first bit lines, a second memory cell array electrically connected to a set of second bit lines, and a sense amplifier that is physically located between the first and second memory cell arrays, and is shared by the first and second memory cell arrays, and shared by the first and second memory cell arrays.

Hereinafter, embodiments will be described with reference to the accompanying drawings. Also, in description below, the same reference symbols are given to elements which have the same functions and configurations.

### [1]First Embodiment

A semiconductor memory device according to a first embodiment will be described. Hereinafter, a three-dimensional semiconductor memory device, in which memory cells are stacked on a semiconductor substrate, will be described as an example of the semiconductor memory device.

[1-1] Configuration

[1-1-1] Entire Configuration

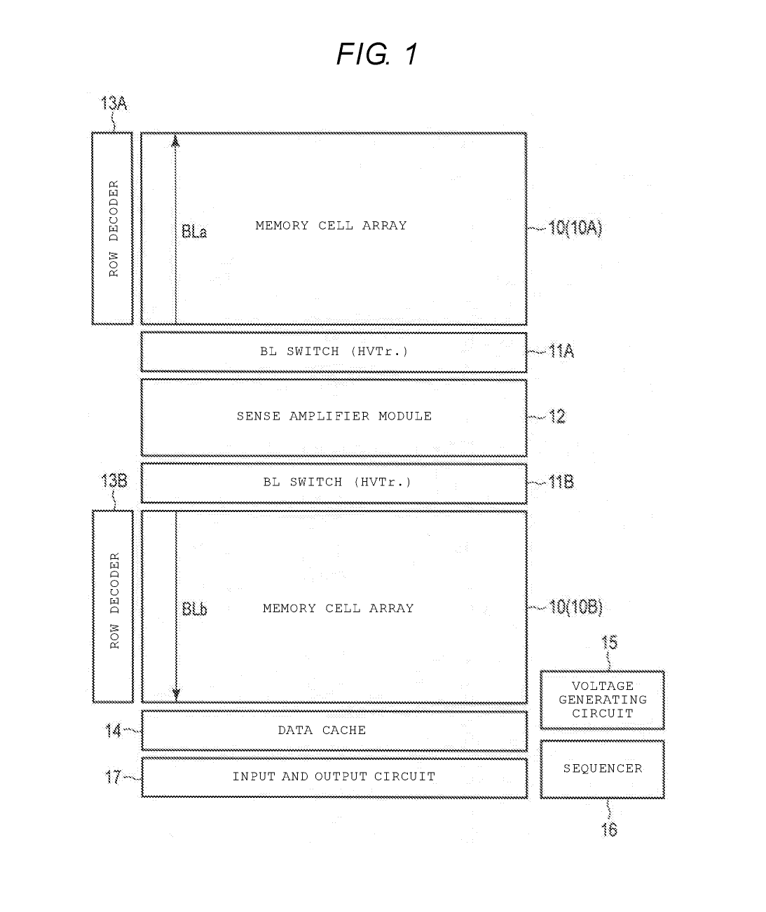

The entire configuration of a semiconductor memory device 1 will be described with reference to FIG. 1.

A semiconductor memory device 1 includes memory cell arrays 10A and 10B, bit line (BL) switching circuits 11A and 11B, a sense amplifier module 12, row decoders 13A and 13B, a data cache 14, a voltage generating circuit 15, a sequencer 16, and an input and output circuit 17.

Each of the memory cell arrays 10A and 10B is a set of nonvolatile memory cells which are associated with word lines and bit lines. The memory cell arrays 10A and 10B share the sense amplifier module 12 which is physically arranged between the memory cell arrays 10A and 10B. The combination of the memory cell arrays 10A and 10B is referred to as a memory cell array 10. In addition, the bit lines BL of the memory cell arrays 10A and 10B are referred to as bit lines BLa and BLb, respectively.

The BL switching circuit 11A electrically connects between the bit line BLa of the memory cell array 10A and the sense amplifier module 12, and the BL switching circuit 11B electrically connects the bit line BLb of the memory cell array 10B and the sense amplifier module 12. Each of the BL switching circuits 11A and 11B includes a high voltage-resistant n-channel transistor (HVTr.).

When data is read, the sense amplifier module 12 senses data, which is read from the memory cells and transferred through the bit lines BL. When data is written, the sense amplifier module 12 transfers data to be written into the memory cells through the bit lines BL.

Each of the row decoders 13A and 13B decodes a block address or a page address, selects one of the word lines WL of a corresponding block BLK, and applies an appropriate voltage to the selected word line and non-selected word lines. The row decoder 13A is provided for the memory cell array 10A, and the row decoder 13B is provided for the memory cell array 10B.

The data cache 14 holds data from the sense amplifier module 12 and the input and output circuit 17. The data cache 14 is used for a cache operation performed by the sense amplifier module 12. The data cache 14 is arranged between the memory cell array 10B and input and output circuit 17.

The voltage generating circuit 15 generates a voltage which is appropriate for the memory cell array 10, the sense amplifier module 12, and the row decoder 13. More specifically, the voltage generating circuit 15 applies a voltage to a well area, in which source lines CELSRC and NAND strings NS are formed, or the like.

The sequencer 16 controls an entire operation performed by the semiconductor memory device 1.

The input and output circuit 17 transfers and receives data to and from a controller or a host device (not shown in the drawing) located outside of the semiconductor memory device 1. When data is read, the input and output circuit 17 outputs read data, which is sensed by the sense amplifier module 12, to the outside through the data cache 14. When data is written, the input and output circuit 17 transfers data to be written, which is received from the outside, to the sense amplifier module 12 through the data cache 14.

[1-1-2] Memory Cell Array 10

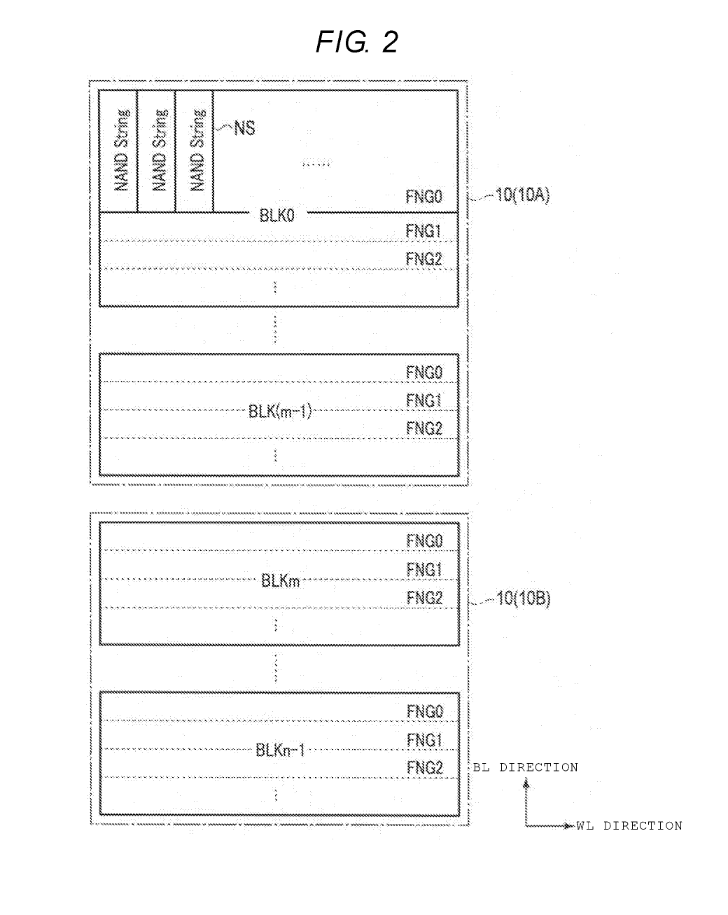

The configuration of the memory cell array 10 will be described with reference to FIG. 2.

The memory cell array 10 includes n blocks BLK (BLK0, BLK1, . . . , BLK (n−1) which are arranged in the direction of a bit line BL, and n is a natural number which is equal to or larger than 1 in general and equal to or larger than 2 in the embodiments). The block BLK is, for example, the unit of erasing data. Data in the same block BLK is erased as one unit. The invention is not limited to the case. Other erasing operations are disclosed in U.S. patent application Ser. No. 13/235,389, “Nonvolatile Semiconductor Memory Device”, filed on Sep. 18, 2011, and U.S. patent application Ser. No. 12/694,690, “Nonvolatile Semiconductor Memory Device”, filed on Jan. 27, 2010. The entire contents of these patent applications are incorporated herein by reference.

Each of the blocks BLK includes a plurality of fingers FNG (FNG0, FNG1, FNG2, . . . ). The fingers FNG are each a set of NAND strings NS, in each of which the memory cells are connected in series. Also, the number of blocks BLK in the memory cell array 10 and the number of fingers FNG in a single block BLK may be set to arbitrary numbers.

The memory cell array 10 is divided into m blocks BLK0 to BLK (m−1) (memory cell array 10A) and (n−m) blocks BLKm to BLK (n−1) (memory cell array 10B). The number of blocks BLK, which are included in each of the memory cell arrays 10A and 10B, may be the same or may be different. Hereinafter, a case in which the number of blocks BLK, which are included in each of the memory cell arrays 10A and 10B, is the same will be described.

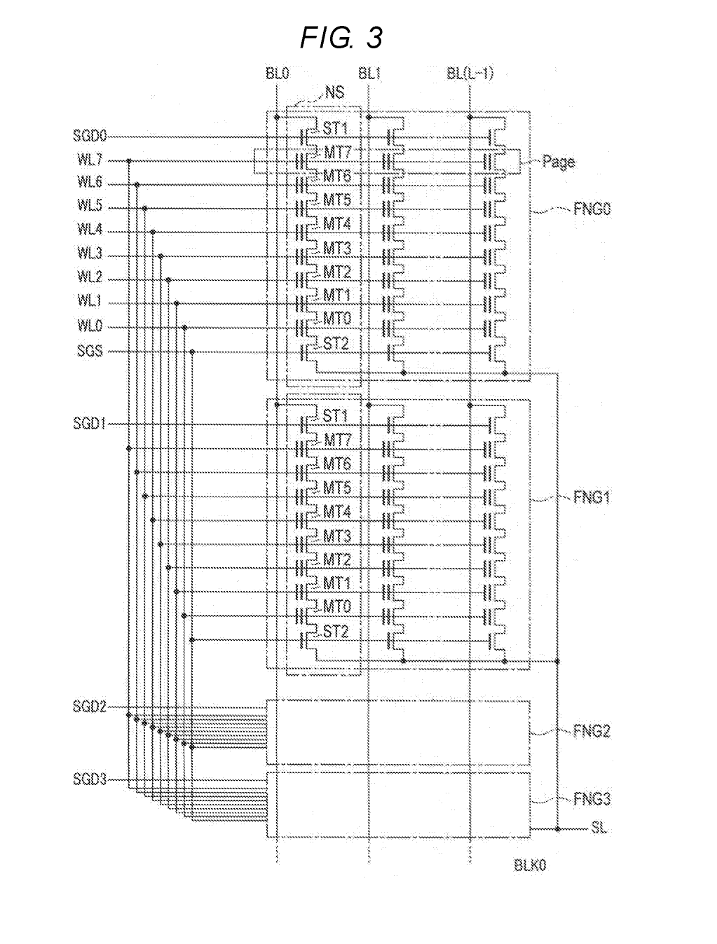

The configuration of a circuit of any one of blocks BLK of the memory cell array 10 will be described with reference to FIG. 3. Other blocks BLK also have the same configuration.

The block BLK includes, for example, four fingers FNG (FNG0 to FNG3). Each of the fingers FNG includes a plurality of NAND strings NS. Each of the NAND strings NS includes, for example, eight memory cell transistors MT (MT0 to MT7), and select transistors ST1 and ST2. Also, the number of memory cell transistors MT and the number of fingers FNG may be set to arbitrary numbers. The number of memory cell transistors MT may also be, for example, 16, 32, 64, or 128.

The memory cell transistors MT include control gates and stacked gates having charge storage layers, and hold data in a non-volatile manner. The memory cell transistors MT are arranged between the select transistors ST1 and ST2 such that the current paths thereof are connected in series. The current path of the memory cell transistor MT7, which is on one end side of the series connection, is connected to one end of the current path of the select transistor ST1, and the current path of the memory cell transistor MT0, which is on the other end side, is connected to one end side of the current path of the select transistor ST2.

In the fingers FNG0 to FNG3, the respective gates of the select transistors ST1 are commonly connected to corresponding select gate lines SGD0 to SGD3, and the respective gates of the select transistors ST2 are commonly connected to the same select gate line SGS across the fingers FNG0 to FNG3. In the same block BLK, the respective control gates of the memory cell transistors MT0 to MT7 are commonly connected to corresponding word lines WL0 to WL7. That is, in the same block BLK, the word lines WL0 to WL7 and the select gate line SGS are commonly connected across the fingers FNG0 to FNG3, and the select gate lines SGD are independent from each other for each of the fingers FNG0 to FNG3.

In NAND strings NS which are arranged in the memory cell array 10 in the matrix shape, the other ends of the current paths of the select transistors ST1 of the NAND strings NS, which are in the same row, are commonly connected to one of the bit lines BL (BL0 to BL(L−1), (L−1) is a natural number which is equal to or larger than 1). That is, the NAND strings NS, which are in the same row, are commonly connected to the bit lines BL across the plurality of blocks BLK. The other ends of the current paths of the select transistors ST2 are commonly connected to a source line SL. The source line SL is commonly connected across, for example, the plurality of blocks BLK.

Data is read and written in a single operation for a plurality of memory cell transistors MT which are commonly connected to one of the word lines WL in one of the fingers FNG of one of the blocks BLK. A unit of reading and writing data is defined as a page.

[1-1-3] Sense Amplifier Module 12 and Data Cache 14

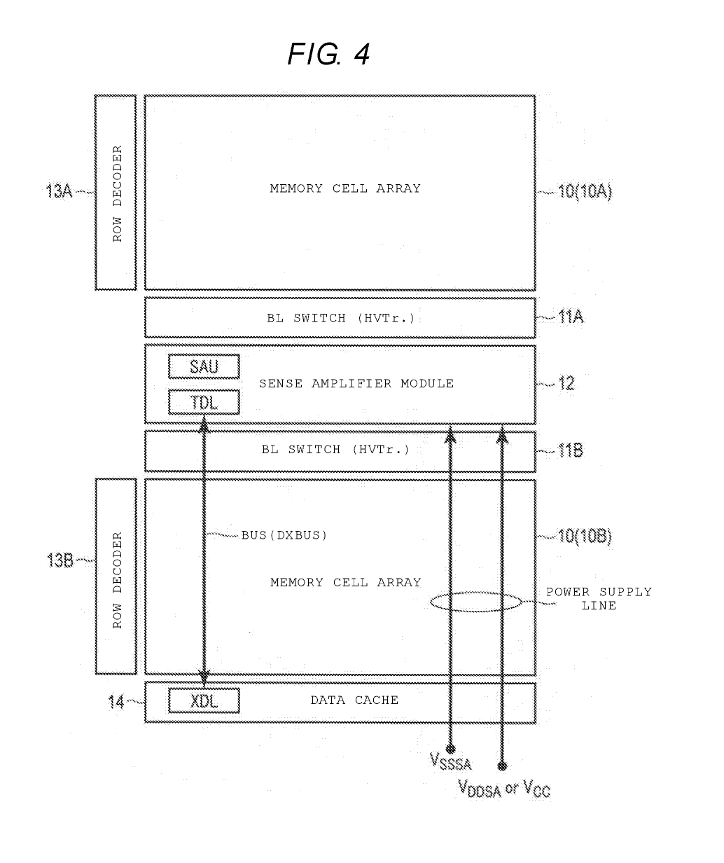

The configurations of the sense amplifier module 12 and the data cache 14 will be described with reference to FIG. 4.

The sense amplifier module 12 includes a plurality of sense amplifier units SAU and a plurality of latch circuits TDL. The data cache 14 includes a plurality of latch circuits XDL. The latch circuits TDL and the latch circuits XDL are connected through buses DXBUS.

A plurality of power supply lines, which supply a power supply voltage VDDSA (or VCC) and a grounding voltage VSSSA, pass through the memory cell array 10B, and are connected to the sense amplifier module 12 and the BL switching circuits 11A and 11B.

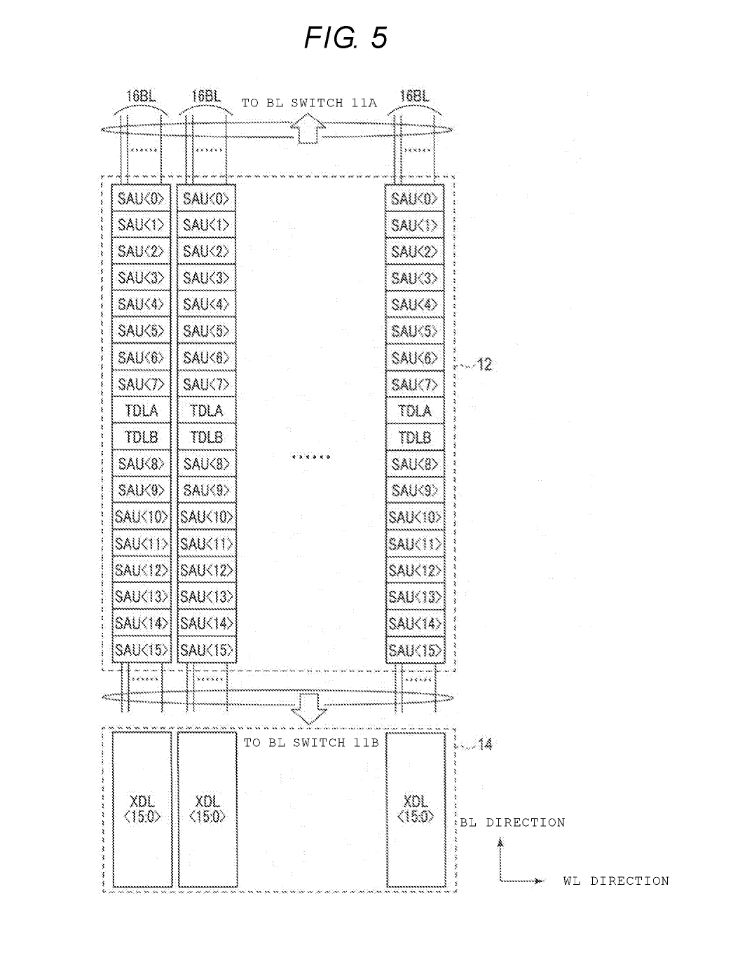

The configurations of the sense amplifier module 12 and the data cache 14 will be described with reference to FIG. 5. For simplification, the memory cell array 10B and the BL switching circuit 11B between the sense amplifier module 12 and the data cache 14 are not described.

The sense amplifier units SAU are each provided for one bit line BL. The sense amplifier units SAU each include a plurality of latch circuits, which will be described later, therein. For example, sixteen sense amplifier units SAU are arranged in a line in the direction along the bit line BL. When the sixteen sense amplifier units SAU are referenced in the description below, the sense amplifier units SAU are expressed as SAU<0> to SAU<15>, respectively. In addition, in the description below, sixteen sense amplifier units SAU are expressed as SAU<15:0>.

Two latch circuits TDL (latch circuits TDLA and TDLB) are provided for the each set of sense amplifier units SAU<15:0> which are arranged in a line. When data is transferred, the latch circuits TDL are used for the cache operations of the sense amplifier units SAU and the latch circuits XDL. For example, a latch circuit TDLA corresponds to the sense amplifier units SAU<0> to SAU<7>, and a latch circuit TDLB corresponds to the sense amplifier units SAU<8> to SAU<15>. The respective latch circuits TDLA and TDLB are arranged with the sense amplifier units SAU in a line, and are inserted, for example, between the sense amplifier units SAU<7> and SAU<8>, as illustrated in FIG. 5. The respective latch circuits TDLA and TDLB may be arranged, for example, at both the ends of the set of sense amplifier units SAU<15:00> one by one, and the invention is not limited thereto.

The latch circuits XDL are provided for the respective bit lines BL, and temporarily hold data for corresponding bit lines BL. The latch circuits XDL are used for the cache operation of the semiconductor memory device 1. Similarly to the sense amplifier units SAU, sixteen latch circuits XDL are provided as one set and are arranged along the bit line direction. In FIG. 5, sixteen latch circuits XDL are expressed as XDL<15:0>. When the latch circuits XDL are empty, the semiconductor memory device 1 may receive data from the outside even when the latch circuits in the sense amplifier units SAU are being used.

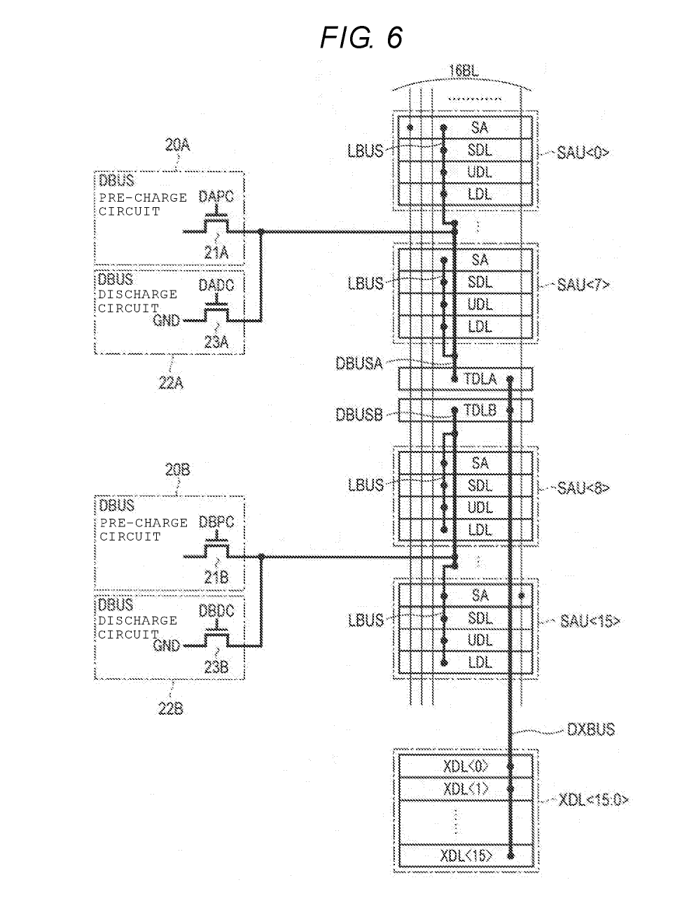

The detailed configurations of the sense amplifier module 12 and the data cache 14 will be described with reference to FIG. 6. FIG. 6 illustrates a set of the sense amplifier units SAU, the latch circuits TDL, and the latch circuits XDL.

The sense amplifier module 12 further includes buses LBUS, pre-charge circuits 20, and discharge circuits 22. Each of the sense amplifier units SAU includes a sense amplifier SA and latch circuits SDL, UDL, and LDL.

The sense amplifier SA is connected to a corresponding bit line BL.

The latch circuits SDL, UDL, and LDL temporarily hold data. The sense amplifier SA operates according to the data held by a latch circuit SDL. The latch circuits UDL and LDL are used such that each of the memory cell transistors performs multi-valued operation for holding data of two or more bits and performs a Quick Pass Write operation. The QPW operation is disclosed in U.S. patent application Ser. No. 14/263,948, “Nonvolatile Semiconductor Memory Device”, filed on Apr. 28, 2014, the entire contents of which are incorporated herein by reference.

In each of the sense amplifier units SAU, the sense amplifier SA and the three latch circuits SDL, UDL, and LDL are connected through a bus LBUS such that data may be transferred and received to and from each other. Also, the bus LBUS may be commonly connected, for example, between two sense amplifier units SAU which are adjacent in the bit line direction. In this case, the two sense amplifier units SAU are arranged along the bit line, and eight buses LBUS are provided for the sixteen sense amplifier units SAU<15:0>.

A bus DBUS connects the sense amplifier units SAU and a corresponding latch circuits TDL to each other, so that the sense amplifier units SAU and the corresponding latch circuits TDL may transfer and receive data to and from each other. In FIG. 6, a set of eight sense amplifier units SAU, which are arranged in a line, share one data bus (a bus DBUSA or a bus DBUSB). More specifically, the bus DBUSA is connected to the bus LBUS, which is connected to each of the sense amplifier units SAU<0> to <7>, and the latch circuit TDLA. The bus DBUSB is connected to the bus LBUS, which is connected to each of the sense amplifier units SAU<8> to <15>, and the latch circuit TDLB.

The buses DXBUS electrically connect the latch circuits TDL and the corresponding latch circuit XDL. In FIG. 6, two latch circuits TDL (latch circuits TDLA and TDLB) share one bus DXBUS. More specifically, the bus DXBUS is connected to the latch circuits TDLA and TDLB and XDL<15:0>.

The pre-charge circuits 20 and the discharge circuits 22 are provided for bus DBUSA and DBUSB, respectively. A pre-charge circuit 20A and a discharge circuit 22A, which correspond to the bus DBUSA, and a pre-charge circuit 20B and a discharge circuit 22B, which correspond to the bus DBUSB, have the same configuration, and the pre-charge circuit 20B and the discharge circuit 22B will not be described. In addition, reference numerals and control signal names of the respective transistors shown it the drawing are described below.

The pre-charge circuit 20A pre-charges the bus DBUSA. For example, the pre-charge circuit 20A includes a low voltage-resistant n-channel MOS transistor 21A that includes one end which is connected to the bus DBUSA and a gate to which a control signal DAPC is applied.

The discharge circuit 22A discharges the bus DBUSA. For example, the discharge circuit 22A includes a low voltage-resistant n-channel MOS transistor 23A that includes one end which is connected to the bus DBUSA, the other end is grounded (VSS), and a gate to which a control signal DADC is applied.

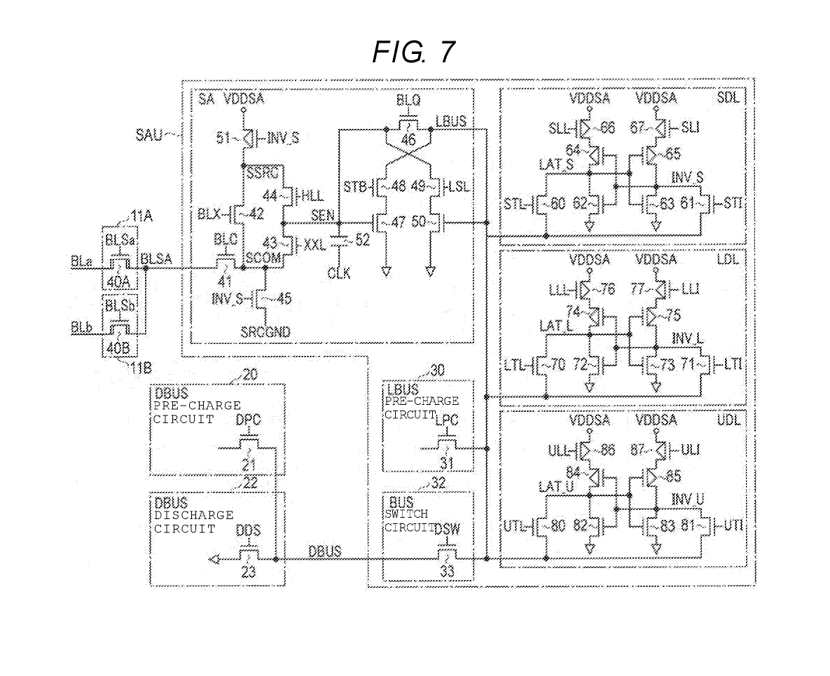

The circuit configurations of the sense amplifier units SAU and the BL switching circuits 11A and 11B will be described with reference to FIG. 7. Also, in the pre-charge circuit 20 and the discharge circuit 22, the control signal DPC corresponds to control signals DAPC and DBPC, and a control signal DDS corresponds to the control signals DADC and DBDC. In addition, a wiring, which connects the bit lines BLa, BLb and the sense amplifiers SAU to each other, is referred to as a bit line BLSA.

The BL switching circuits 11A and 11B includes high voltage-resistant n-channel MOS transistors 40A and 40B, respectively. The transistors 40A and 40B include one ends which are respectively connected to the bit lines BLa and BLb, the other ends which are connected to the bit line BLSA, and gates to which control signals BLSa and BLSb are input.

Each of the sense amplifier units SAU further includes a pre-charge circuit 30 and a bus switch circuit 32.

The pre-charge circuit 30 pre-charges the bus LBUS. For example, the pre-charge circuit 30 includes a low voltage-resistant n-channel MOS transistor 31 that includes one end which is connected to the bus LBUS, and a gate to which a control signal LPC is applied.

The bus switch 32 connects the bus DBUS and the bus LBUS. For example, the bus switch 32 includes a low voltage-resistant n-channel MOS transistor 33 that includes one end which is connected to the bus DBUS, the other end which is connected to the bus LBUS, and a gate to which a control signal DSW is applied.

The configuration of the sense amplifier SA will now be described.

The sense amplifier SA includes low voltage-resistant n-channel MOS transistors 41 to 50, a low voltage-resistant p-channel MOS transistor 51, and a capacitor element 52.

The transistor 41 includes one end which is connected to the bit line BLSA, the other end which is connected to a node SCOM, and a gate to which a signal BLC is input. The transistor 41 clamp the corresponding bit line BL to an electrical potential according to the signal BLC.

The transistor 45 includes one end which is connected to the node SCOM, the other end which is connected to a node SRCGND (for example, 0 V), and a gate which is connected to a node INV_S. The transistor 42 includes one end which is connected to the node SCOM, the other end which is connected to a node SSRC, and a gate to which a control signal BLX is input. The transistor 51 includes one end which is connected to the node SSRC, the other end to which the power supply voltage VDDSA is applied, and a gate which is connected to the node INV_S.

The transistor 43 includes one end which is connected to the node SCOM, the other end which is connected to a node SEN, and a gate to which a control signal XXL is input. The transistor 44 includes one end which is connected to the node SSRC, the other end which is connected to the node SEN, and a gate to which a control signal HLL is input. The capacitor element 52 includes one side electrode which is connected to the node SEN, and the other side electrode to which a clock CLK is input. The transistor 47 includes one end which is grounded, and a gate which is connected to the node SEN. The transistor 48 includes one end which is connected to the other end of the transistor 47, the other end which is connected to the bus LBUS, and a gate to which a control signal STB is input.

The transistor 46 includes one end which is connected to the node SEN, the other end which is connected to the bus LBUS, and a gate to which a control signal BLQ is input. The transistor 50 includes one end which is grounded, and a gate which is connected to the bus LBUS. The transistor 49 includes one end which is connected to the other end of the transistor 50, the other end which is connected to the node SEN, and a gate to which a control signal LSL is input.

The configuration of the latch circuit SDL will now be described.

The latch circuit SDL includes low voltage-resistant n-channel MOS transistors 60 to 63 and low voltage-resistant p-channel MOS transistor 64 to 67.

The transistor 60 includes one end which is connected to the bus LBUS, the other end which is connected to a node LAT_S, and a gate to which a control signal STL is input. The transistor 61 includes one end which is connected to the bus LBUS, the other end which is connected to the node INV_S, and a gate to which a control signal STI is input. The transistor 62 includes one end which is grounded, the other end which is connected to the node LAT_S, and a gate which is connected to the node INV_S. The transistor 63 includes one end which is grounded, the other end which is connected to the node INV_S, and a gate which is connected to the node LAT_S. The transistor 64 includes one end which is connected to the node LAT_S, and a gate which is connected to the node INV_S. The transistor 65 includes one end which is connected to the node INV_S and a gate which is connected to the node LAT_S. The transistor 66 includes one end which is connected to the other end of the transistor 64, the other end to which the power supply voltage VDDSA is applied, and a gate to which a control signal SLL is input. The transistor 67 includes one end which is connected to the other end of the transistor 65, the other end to which the power supply voltage VDDSA is applied, and a gate to which the control signal SLI is input.

In the latch circuit SDL, a first inverter is formed by the transistors 62 and 64, and a second inverter is formed by the transistors 63 and 65. Further, the output of the first inverter and the input of the second inverter (node LAT_S) are connected to the bus LBUS through the transistor 60 for transferring data, and the input of the first inverter and the output (node INV_S) of the second inverter are connected to the bus LBUS through the transistor 61 for transferring data. The latch circuit SDL holds data at the node LAT_S, and holds the inversion data thereof at the node INV_S.

Each of the latch circuits LDL and UDL includes the same configuration as that of the latch circuit SDL, and thus the description thereof will be omitted. In the latch circuits LDL and UDL, reference numerals and control signal names of the respective transistors are distinguished from those of the latch circuit SDL.

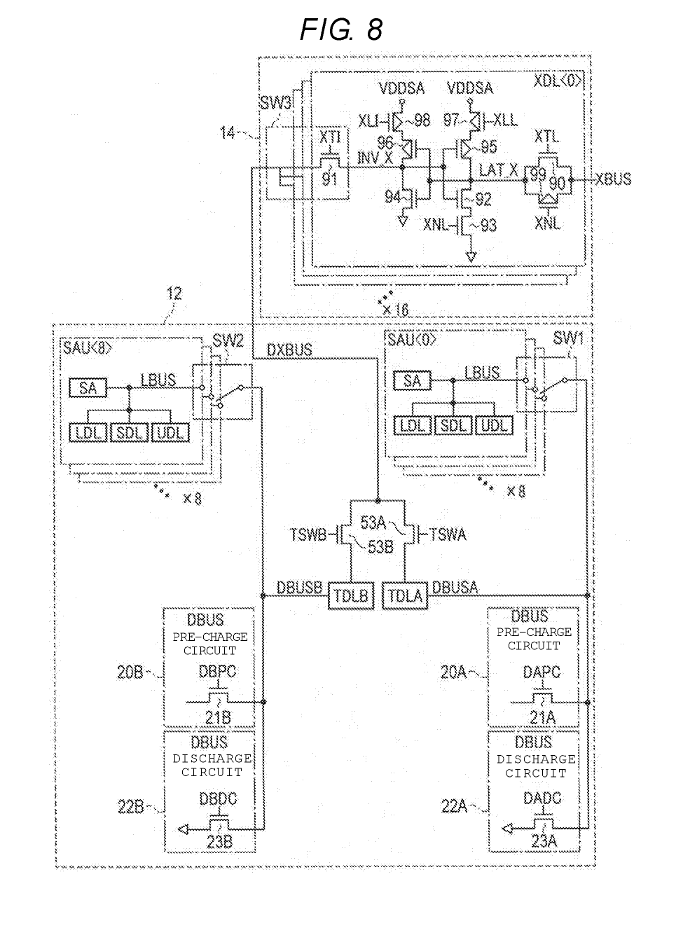

The circuit configuration of the latch circuits TDL and XDL will be described with reference to FIG. 8. Since the latch circuits TDL and XDL have a similar circuit configuration, only the circuit configuration of the latch circuit XDL is illustrated in FIG. 8.

The latch circuit XDL includes low voltage-resistant n-channel MOS transistors 90 to 94 and low voltage-resistant p-channel MOS transistors 95 to 99.

The transistor 90 includes one end which is connected to a bus XBUS that is connected to the input and output circuit 17, the other end which is connected to a node LAT_X, and a gate to which a control signal XTL is input. The transistor 91 includes one end which is connected to the bus DXBUS, the other end which is connected to a node INV_X, and a gate to which a control signal XTI is input. The transistor 92 includes one end which is connected to the node LAT_X and a gate which is connected to the node INV_X. The transistor 93 includes one end which is grounded, the other end which is connected to the other end of the transistor 92, and a gate to which a control signal XNL is input. The transistor 95 includes one end which is connected to the node LAT_X, and a gate which is connected to the node INV_X. The transistor 96 includes one end which is connected to the node INV_X, and a gate which is connected to the node LAT_X. The transistor 97 includes one end which is connected to the other end of the transistor 95, the other end to which the power supply voltage VDDSA is applied, and a gate to which a control signal XLL is input. The transistor 98 includes one end which is connected to the other end of the transistor 96, the other end to which the power supply voltage VDDSA is applied, and a gate to which a control signal XLI is input. As described above, the latch circuit XDL has a configuration which is substantially similar to the latch circuit SDL or the like, and holds data between the bus DXBUS and a bus XBUS.

The connection relationship between the sense amplifier units SAU and the latch circuits TDL and XDL will now be described.

The sense amplifier module 12 further includes low voltage-resistant n-channel MOS transistors 53A and 53B. The respective transistors 53A and 53B include one ends which are respectively connected to the one ends of the latch circuits TDLA and TDLB, the other ends which are connected to the bus DXBUS, and gates to which control signals TSWA and TSWB are respectively input. The latch circuits TDLA and TDLB include the other ends which are respectively connected to the buses DBUSA and DBUSB.

The connection between the sense amplifier units SAU<0> to <7> and the bus DBUSA is switched by a first switch SW1, and the connection between the sense amplifier units SAU<8> to <15> and the bus DBUSB is switched by a second switch SW2. The connection between two sets of sense amplifier units SAU<0> to <7> and SAU<8> to <15> and the bus DXBUS is switched by control signals TSWA and TSWB which are input to the gate of the transistors 53A and 53B. The connection between the 16 latch circuits XDL<15:0> and the bus DXBUS is switched by a third switch SW3.

As described above, the 16 sense amplifier units SAU<15:0> and the 16 latch circuits XDL<15:0> are electrically connected through the single bus DXBUS.

[1-1-4] Sectional Configuration

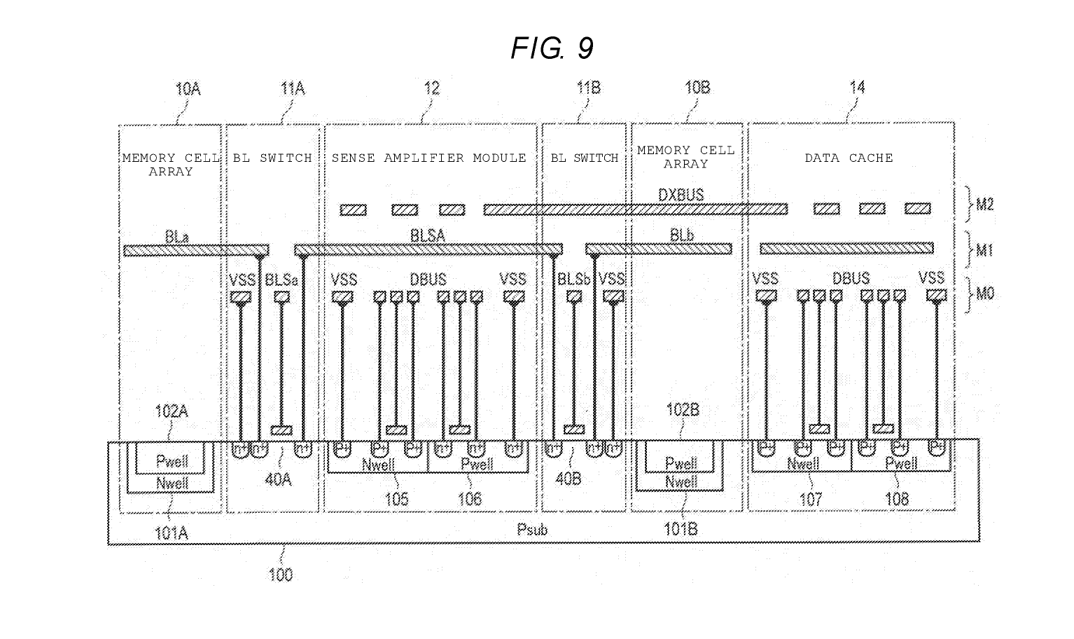

The sectional structure of the semiconductor memory device 1 will be described with reference to FIG. 9.

FIG. 9 illustrates the sectional structure of the memory cell arrays 10A and 10B, the BL switching circuits 11A and 11B, the sense amplifier module 12, and the data cache 14 in the direction of bit line BL. In FIG. 9, the structures of the memory cell arrays 10A and 10B are not illustrated in the drawing. Also, a layer M0 indicates the lowermost layer of the metal wiring layer of the semiconductor memory device 1, a layer M1 indicates a metal wiring layer which is one layer above the layer M0, and a layer M2 indicates a metal layer which is one layer above the layer M1, and the layers are used in the description below.

In the respective areas of the memory cell arrays 10A and 10B, a p-type silicon substrate 100 is formed with n-type well areas 101A and 101B on the surface thereof, and the n-type well areas 101A and 101B are formed with p-type well areas 102A and 102B, respectively, on the surface thereof. Each of the memory cell arrays 10A and 10B is electrically insulated from the p-type silicon substrate 100 by the above-described triple well structure. Each of the bit lines BLa and BLb is arranged on the layer M1. The detailed sectional structure of the memory cell arrays 10A and 10B will be described later.

In the respective areas of the BL switching circuits 11A and 11B, transistors 40A and 40B are formed on the surface of the p-type silicon substrate 100. The respective gates of the transistors 40A and 40B are connected to the wirings of the layer M0.

In the area of the sense amplifier module 12, an n-type well area 105 and a p-type well area 106 are formed on the surface of the p-type silicon substrate 100. In each of the n-type well area 105 and the p-type well area 106, the transistors included in the sense amplifier module 12 are formed, and a grounding voltage VSS is applied. The wirings are connected to the wirings corresponding to the layer M0. In the layer M0, for example, the bus DBUS is arranged. In the layer M1, the bit line BLSA is arranged. In the layer M2, for example, wirings, such as the bus DXBUS, are arranged.

In the area of the data cache 14, an n-type well area 107 and a p-type well area 108 are formed on the surface of the p-type silicon substrate 100. In each of the n-type well area 107 and the p-type well area 108, transistors included in the data cache 14 are formed and the grounding voltage VSS is applied. The wirings are connected to the wirings corresponding to the layer M0. In the layer M2, for example, wirings, such as the bus DXBUS, are arranged.

The bus DXBUS is arranged on the layer M2, and passes through the memory cell array 10B. The bus DXBUS is extended from the area of the sense amplifier module 12 to the area of the data cache 14. Similarly, power supply lines (not shown in the drawing), which supply the power supply voltage VDDSA or the grounding voltage VSS to the sense amplifier module 12, are arranged on the layer M2.

The above-described configuration represents one solution to the problem of the wiring resources of layer M1 not being sufficient when the memory cell arrays 10A and 10B share a single sense amplifier module 12.

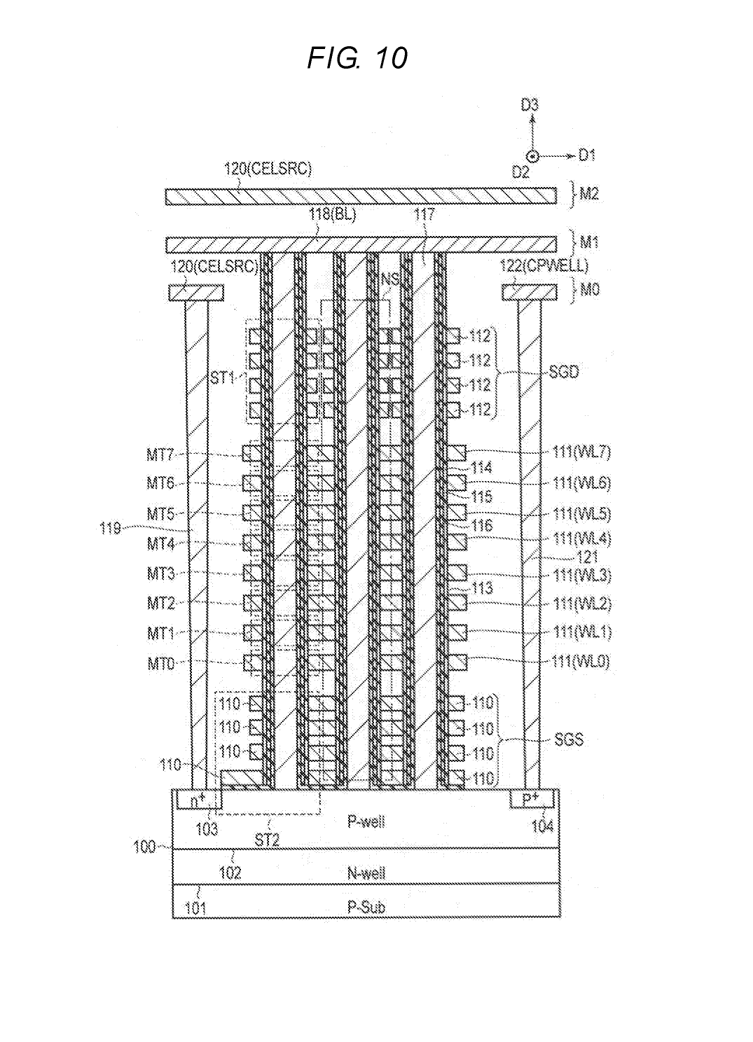

The detailed sectional structure of the memory cell array 10 will be described with reference to FIG. 10.

As illustrated in FIG. 10, a plurality of NAND strings NS are formed on a p-type well area 102. More specifically, on the p-type well area 102, a plurality of wiring layers 110 which function as the select gate line SGS, a plurality of wiring layers 111 which function as the word lines WL, and a plurality of wiring layers 112 which function as the select gate lines SGD, are formed.

The wiring layers 110 are formed, for example, by four layers, and are electrically connected to the select gate line SGS which is common to a plurality of NAND string NS, and function as the two gate electrodes of the select transistor ST2.

The wiring layers 111 are formed, for example, by eight layers, and are electrically connected to the word lines WL which are common for the respective layers.

The wiring layers 112 are formed, for example, by four layers, and are connected to the select gate line SGD which is provided separately for each of the NAND strings NS. Each of the wiring layers 112 functions as the gate electrode of a single select transistor ST1.

Memory holes 113 are formed to penetrate the wiring layers 110, 111, and 112 and to reach the p-type well area 102. On the side surfaces of the memory holes 113, block insulation films 114, charge storage layers 115 (insulation film), and gate insulation films 116 are sequentially formed. In the memory holes 113, conductive films 117 are embedded. The conductive films 117 function as the current paths of the NAND strings NS. A wiring layer 118, which functions as the bit line BL, is formed on the upper ends of the conductive films 117.

As described above, on the p-type well area 102, the select transistor ST2, the plurality of memory cell transistors MT, and the select transistor ST1 are sequentially stacked. Further, a single memory hole 113 corresponds to a single NAND string NS.

On the surface of the p-type well area 102, an n⁺-type impurity diffusion layer 103 and a p⁺-type impurity diffusion layer 104 are formed.

A contact plug 119 is formed on the n⁺-type impurity diffusion layer 103, and the wiring layer 120, which functions as a source line CELSRC, is formed on the contact plug 119. The source line CELSRC is also formed in the layer M2, and the source line CELSRC in the layer M2 is electrically connected to the voltage generating circuit 15.

A contact plug 121 is formed on the p⁺-type impurity diffusion layer 104, and a wiring layer 122, which functions as a well wiring CPWELL, is formed on the contact plug 121. The well wiring CPWELL is electrically connected to the voltage generating circuit 15.

The layer M0, in which the wiring layers 120 and 122 are formed, is formed above the wiring layer 112 (select gate line SGD) and is formed under the layer M1 in which the wiring layer 118 is formed.

The above configuration is arranged in plural along the depth direction of the paper on which FIG. 10 is illustrated. A single finger FNG includes a set of a plurality of NAND strings NS which are formed in a line in the depth direction.

Further, the wiring layers 110 function as a common select gate line SGS in the same block BLK, and are electrically connected to each other. The gate insulation film 116 is formed between the wiring layers 110 in the lowermost layer and the p-type well area 102. The wiring layer 110 in the lowermost layer, which is adjacent to the n⁺-type impurity diffusion layer 103, and the gate insulation film 116 are formed up to the vicinity of the n⁺-type impurity diffusion layer 103.

Therefore, when the select transistor ST2 is in an on-state, a formed channel electrically connects the memory cell transistor MT0 and the n⁺-type impurity diffusion layer 103. The voltage generating circuit 15 may apply electrical potential to the conductive film 117 by applying a voltage to the well wiring CPWELL.

Also, the configuration of the memory cell array 10 may include other configurations. Other configurations of the memory cell array 10 are disclosed in, for example, U.S. patent application Ser. No. 12/407,403, “Three-dimensionally Laminated Nonvolatile Semiconductor Memory”, filed on Mar. 19, 2009, and in addition, U.S. patent application Ser. No. 12/406,524, “Three-dimensionally Laminated Nonvolatile Semiconductor Memory”, filed on Mar. 18, 2009, U.S. patent application Ser. No. 12/679,991, “Nonvolatile Semiconductor Memory Device and Manufacturing Method Thereof”, filed on Mar. 25, 2010, and U.S. patent application Ser. No. 12/532,030, “Semiconductor Memory and Manufacturing Method Thereof”, filed on Mar. 23, 2009. The entire contents of all of these patent application are incorporated herein by reference.

[1-2] Operation

[1-2-1] BL Switching Circuits 11A and 11B

The operations of the BL switching circuits 11A and 11B will be described with reference to FIG. 7. The operation, which is described below, is performed, for example, under the control of the sequencer 16. Various control signals, which are described with reference to FIG. 7, are generated by, for example, the sequencer 16.

When data, which is stored in the memory cells of the memory cell array 10A, is read and written, the sequencer 16 sets a control signal BLSa to an “H” level and turns on the transistor 40A. Therefore, a current path is formed between the bit line BLa, to which target memory cells are connected, and the bit line BLSA. In contrast, the sequencer 16 sets a control signal BLSb to an “L” level, and turns off the transistor 40B. Therefore, the current path is cut off between the bit line BLb, which is arranged in the memory cell array 10B that does not include the target memory cells, and the bit line BLSA.

Similarly, when data, which is stored in the memory cells of the memory cell array 10B, is read and written, the sequencer 16 sets a control signal BLSb to the “H” level, and turns on the transistor 40B. Therefore, a current path is formed between the bit line BLb, to which the specified memory cells are connected, and the bit line BLSA. In contrast, the sequencer 16 sets the control signal BLSa to an “L” level, and turns off the transistor 40A. Therefore, the current path is cut off between the bit line BLa, which is arranged in the memory cell array 10A that does not include the target memory cells, and the bit line BLSA.

As described above, when data is read and written by the sequencer 16, the BL switching circuits 11A and 11B electrically connect one of the memory cell arrays 10A and 10B with the sense amplifier module 12.

[1-2-2] Sense Amplifier Unit SAU

An operation performed when the sense amplifier units SAU read data will be described with reference to FIG. 7.

When a threshold is increased by injecting electric charge into the memory cell transistor MT, the “H” level (data “1”) is stored in the node INV_S of the latch circuit SDL. As a result, the transistor 45 is in the on-state, and the bit line BLSA is connected to the node SRCGND (for example, 0 V). In contrast, when the electric charge is not injected into the memory cell transistor MT and the threshold is not changed, an “L” level (data “0”) is stored in the node INV_S of the latch circuit SDL. As a result, the transistor 51 is in the on-state, and the power supply voltage VDDSA (for example, 2.5 V) is applied to the bit line BLSA.

An operation performed when the sense amplifier units SAU read data will now be described.

When data, which is stored in the memory cell transistor MT, is read, the node INV_S is first set to the “L” level, and thus the transistor 51 is in the on-state. Further, the bit line BLSA is pre-charged up to the power supply voltage VDDSA through the transistors 41 and 42. In addition, the transistor 44 is also in the on-state, and the node SEN is charged up to prescribed electrical potential. Thereafter, the transistor 44 is in the off-state, the signal XXL is set to the “H” level, and thus the transistor 43 is in the on-state. When the target memory cells are in the on-states, the electrical potential of the node SEN is lowered, and thus the transistor 47 is in the off-state. In contrast, when the target memory cells are in the off-states, the electrical potential of the node SEN maintains the “H” level, and the transistor 47 is in an on-state. Further, the signal STB is in the on-state, and the electrical potential according to the on/off of the transistor 47 is held in the bus LBUS. The read electrical potential is held by any one of the latch circuits SDL, LDL, and UDL.

[1-2-3] Data Transmitting Operation Between Latch Circuits

When data is transferred between the latch circuits, the semiconductor memory device 1 reduces current consumption by realizing the lower amplitude of the data bus.

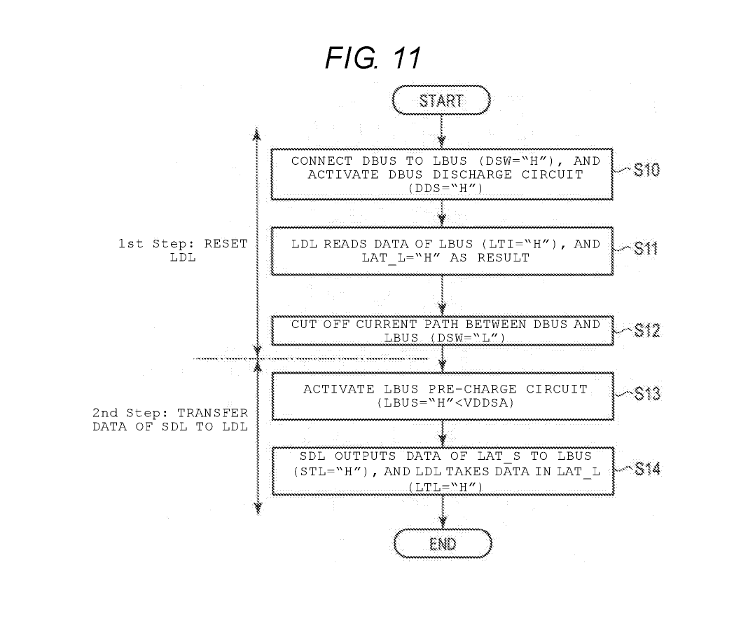

A data transfer operation, which is performed between the latch circuits SDL, LDL, and UDL, will be described with reference to FIGS. 11 to 14. Hereinafter, a case in which data is transferred from the latch circuit SDL to the latch circuit LDL will be described as an example.

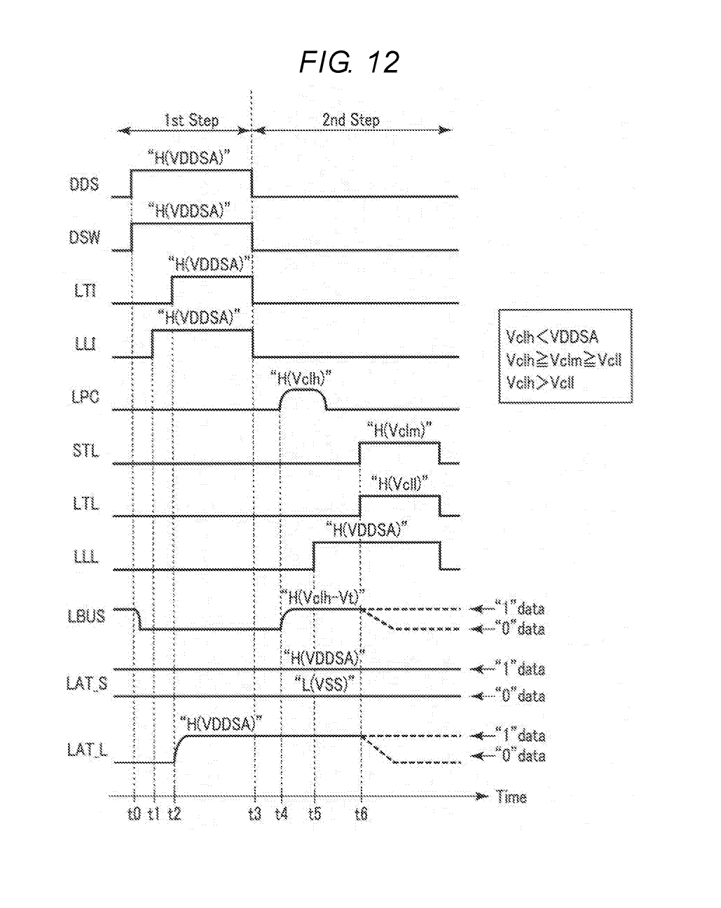

As illustrated in FIGS. 11 and 12, the data transfer operation, which is performed between the latch circuits, includes two steps. A first step is a reset operation of the LDL (transfer destination latch circuit), and a second step is an operation of transferring data from SDL (which holds transfer data, transfer source latch circuit) to the LDL. An operation, which is described below, is performed, for example, under the control of the sequencer 16, and the various control signals, which are described with reference to FIGS. 7 and 8, are generated, for example, by the sequencer 16.

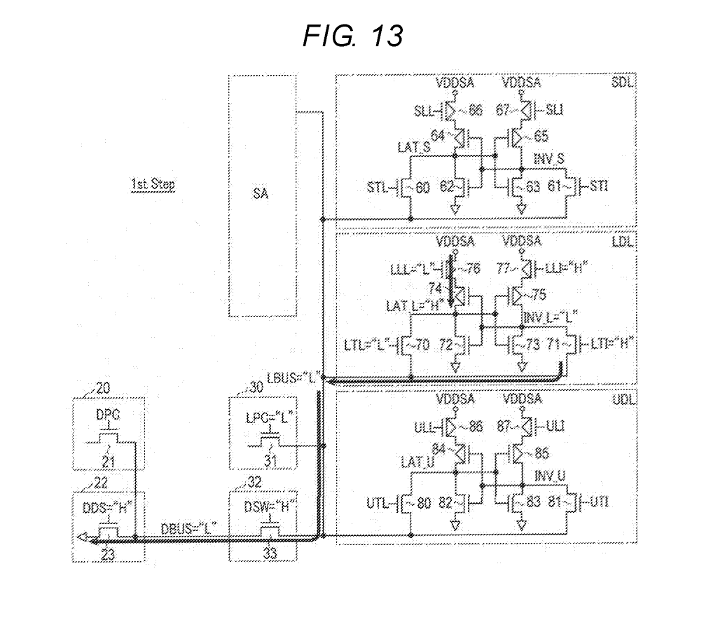

First, the first step will be described below with reference to the circuit diagram of FIG. 13. The sequencer 16 sets the signal DSW to an “H” level, connects the bus DBUS to any one of the buses LBUS, and sets the signal DDS to the “H” level, thereby activating the discharge circuit 22 (step S10, time t0). Therefore, the bus DBUS and the bus LBUS are discharged, and the electrical potential of the bus DBUS and the bus LBUS becomes the “L” level (substantially 0 V), as illustrated in FIG. 13. Also, the electrical potential of the signals DSW and DDS, which are set to the “H” levels, is set to be the power supply voltage VDDSA of the latch circuit SDL. The potential of other control signals is acquired in the same manner unless otherwise described in the specification.

Subsequently, the sequencer 16 sets the signals LLL and LLI to the “L” level and the “H” level respectively (time t1), and turns the transistors 76 and 77 on and off, respectively. Further, the sequencer 16 sets a signal LTI to the “H” level (time t2), and turns the transistor 71 on. Therefore, the LDL, which is the data transfer destination, acquires the electrical potential of the bus LBUS. That is, the node INV_L becomes the “L” level, and a node LAT_L becomes the “H” level (VDDSA) (step S11).

Subsequently, the sequencer 16 sets the signal DSW to the “L” level, and turns the transistor 33 off. Therefore, the current path between the buses DBUS and LBUS is cut off (step S12, time t3).

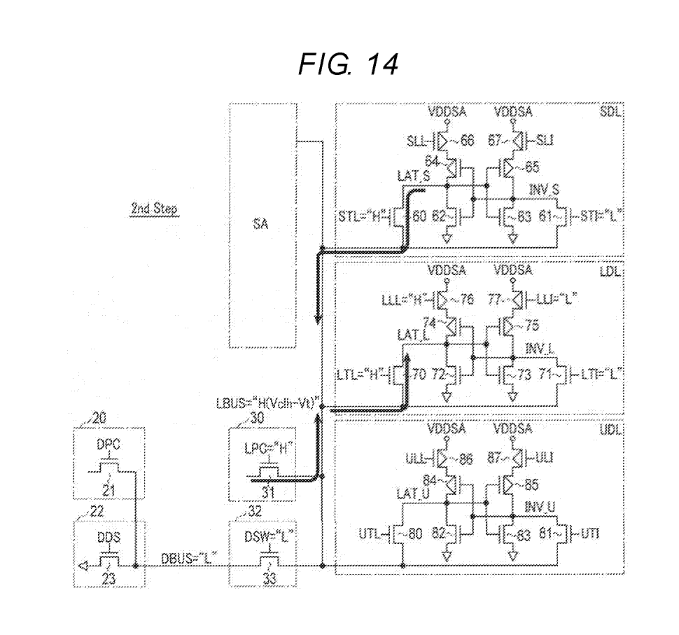

Subsequently, the second step will be described below with reference to the circuit diagram of FIG. 14. First, the sequencer 16 sets the signal LPC to the “H” level, activates the pre-charge circuit 30, and pre-charges the bus LBUS (time t4). At this time, for example, the sequencer 16 sets the electrical potential of the signal LPC to Vclh, and the sequencer 16 controls the transistor 31 such that the electrical potential of the bus LBUS is (Vclh−Vt), which is, for example, 0.5 to 1 V (step S13). The voltage Vclh is a voltage which is lower than the power supply voltage VDDSA of the sense amplifier units SAU, and the voltage Vt is a threshold voltage of the low voltage-resistant n-channel transistor (for example, transistor 31, 60, 61, 70, 71, 80, or 81) in the sense amplifier units SAU. Therefore, the electrical potential of the bus LBUS is clamped to (Vclh−Vt). Otherwise, the electrical potential of the signal LPC may be sufficiently raised, and Vclh may be applied to the other end of the current path of the transistor 31.

Subsequently, the sequencer 16 sets the signal LLL to the “H” level during a period in which the signal LPC is set as the “H” level (time t5). Therefore, the electrical potential of the node LAT_L of LDL is VDDSA. Further, after the sequencer 16 sets the signal LPC to the “L” level, the sequencer 16 sets the signals STL and LTL to the “H” level (time t6). Therefore, SDL outputs the data of LAT_S to the bus LBUS, and LDL acquires the data in LAT_L (step S14). Also, the electrical potential Vclm and Vcll of the signals STL and LTL are lower than VDDSA. Also, the relationship with Vclh is as below.

Vclh≧Vclm≧Vcll

Vclh>Vcll

Here, Vclh≧Vclm (more preferably, Vclh>Vclm) is a condition in which SDL stably holds data “1”, and Vclh≧Vcll (more preferably, Vclh>Vcll) is a condition in which LDL stably holds data “1”. The reason for this is that, when SDL and LDL hold the “H” level and the gate voltages of transfer transistors 60 and 70 are too high, the transistors are turned on, and thus there is a problem in that the data held by SDL and LDL is damaged.

In addition, as an example, the values of Vclh, Vclm, and Vcll are set as below.

Vclh=1V+Vt

Vclm=0.75V+Vt

Vcll=0.5V+Vt

When the signal STL is set to the “H” level, the electrical potential of the bus LBUS changes according to the data which is held by SDL (data of LAT_S). When SDL holds data “1”, the electrical potential of the bus LBUS maintains the “H” level (Vclh−Vt). At this time, the node LAT_L continues holding the “H” level (VDDSA). In contrast, when SDL holds data “0”, the electrical potential of the bus LBUS transitions to the “L” level (0 V). When the bus LBUS transitions to the “L” level (0 V), the “L” level is stored in the node LAT_L.

As described above, the transfer destination latch circuit is caused to hold “1”, and, thereafter, the transfer source latch circuit outputs data. When the transfer data is “0”, data “0” is transferred to the transfer destination latch circuit. When the transfer data is “1”, the transfer destination latch circuit retains data “1”.

As described above, when data is transferred between the latch circuits, the semiconductor memory device 1 sets the electrical potential for pre-charging the bus LBUS as the voltage Vclh−Vt which is lower than the power supply voltage VDDSA. Therefore, since a current, which is necessary for charging the bus LBUS, is reduced when data transfer is performed, the current consumption of the semiconductor memory device 1 is reduced.

Also, similarly, in the data transfer between the latch circuits TDL and XDL, it is possible to reduce the current consumption of the semiconductor memory device 1 by setting electrical potential for pre-charging the bus DXBUS to a voltage which is lower than the power supply voltage VDDSA.

[1-2-4] Data Transmission Operation Between Sense Amplifier Unit SAU and Latch Circuit XDL

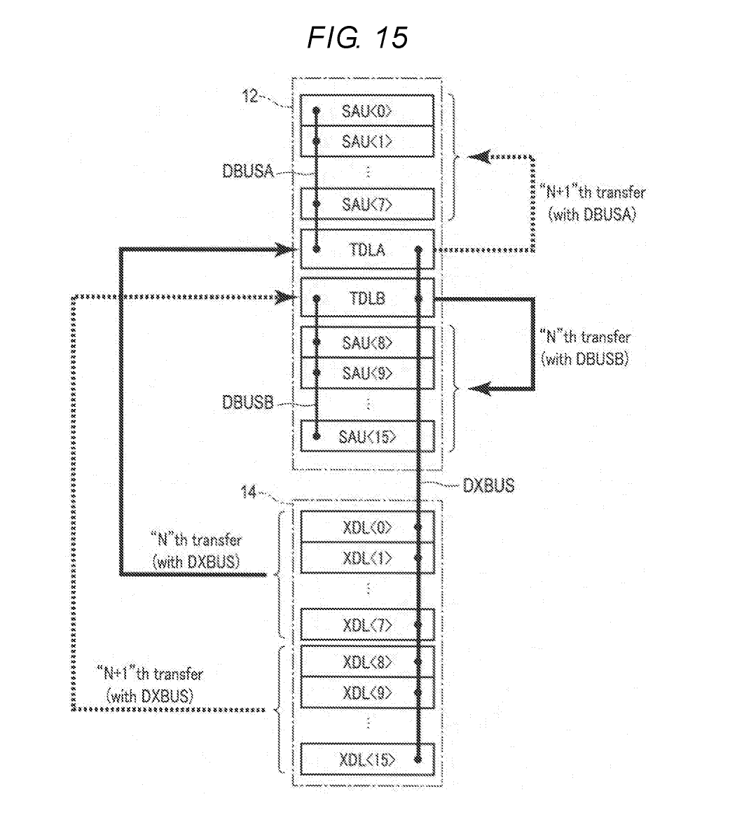

The data transfer operation between the sense amplifier units SAU and the latch circuits XDL when data is read will be described with reference to FIG. 15. Since data is read in inverse order by which the data is written, the transfer operation which is performed when the data is read will not be described. Control of the sense amplifier units SAU and the latch circuits XDL when data is transferred, is performed, for example, by the sequencer 16.

First, the sequencer 16 transfers data, which is held in the latch circuit XDL<0> data, to the latch circuit TDLA through the bus DXBUS.

Subsequently, the sequencer 16 transfers data, which is transferred to the latch circuit TDLA, to the sense amplifier unit SAU<0> through the bus DBUSA, and transfers data, which is held in the latch circuit XDL<8>, to the latch circuit TDLB through the bus DXBUS.

Subsequently, the sequencer 16 transfers data, which is transferred to the latch circuit TDLB, to the sense amplifier unit SAU<8> through the bus DBUSB, and transfers data, which is held in the latch circuit XDL<1>, to the latch circuit TDLA through the bus DXBUS.

The sequencer 16 repeats the above operation by increasing the addresses of the sense amplifier units SAU and the latch circuits XDL. More specifically, the sequencer 16 transfers data, which is held in the latch circuits XDL<0> to <7> and XDL<8> to <16>, to the sense amplifier units SAU<0> to <7> and SAU<8> to <15> through the latch circuits TDLA and TDLB, respectively, as illustrated in FIG. 15.

Finally, after the data, which is held in the latch circuit XDL<15>, is transferred to the latch circuit TDLB, the sequencer 16 transfers the data, which is transferred to the latch circuit TDLB, to the sense amplifier unit SAU<15> through the bus DBUSB.

As described above, the data of the 16 latch circuits XDL<15:0> is transferred to the 16 corresponding sense amplifier units SAU<15:0>. When data transfer from the latch circuits XDL to the latch circuit TDLA or TDLB and data transfer from the latch circuit TDLA or TDLB to the sense amplifier units SAU are simultaneously performed, it is possible to effectively transfer data.

In addition, the sense amplifier module 12 performs data transfer by charging only the bus DBUS (the bus DBUSA or DBUSB) corresponding to the sense amplifier units SAU of the data transfer destination. Therefore, compared to a case in which the bus DBUSA is not separated from the bus DBUSB, current consumption between the latch circuits TDL and the sense amplifier units SAU is lowered.

Also, the order of data transfer between the latch circuits XDL<15:0> and the relevant sense amplifier units SAU<15:0> may be reversed and the invention is not limited thereto.

[1-3] Advantage of First Embodiment

The semiconductor memory device 1 according to the first embodiment divides the memory cell array 10 into two (memory cell arrays 10A and 10B) in the direction of bit line BL. Therefore, the lengths of the wirings of the bit lines BLa and BLb respectively corresponding to the memory cell arrays 10A and 10B are shorter than the length of the wiring of the bit line BL in a case in which division is not performed on the memory cell array 10 (comparison example).

In addition, the memory cell arrays 10A and 10B share a single sense amplifier (sense amplifier module 12) which is arranged between the memory cell arrays 10A and 10B, and the BL switching circuits 11A and 11B are provided between the memory cell array 10A and the sense amplifier module 12 and between the sense amplifier module 12 and the memory cell array 10B, respectively. The BL switching circuits 11A and 11B electrically connects one of the memory cell arrays 10A and 10B to the sense amplifier module 12 using the sequencer 16.

According to the above configuration, in the semiconductor memory device 1 according to the first embodiment, it is possible to substantially halve the length of the wiring of the bit line BL to be charged, compared to a comparison example. For example, when the length of the wiring of the bit line BL is halved, the parasitic capacitance and the resistance value of the wiring are halved, respectively. Therefore, a time which is necessary to charge the bit line BL becomes shorter and thus reading and writing times become shorter. That is, the operation of the semiconductor memory device 1 is performed at higher speeds, and current consumption is reduced, for example, to a quarter. In addition, since the memory cell arrays 10, which are acquired through division, share the single sense amplifier module 12, it is possible to suppress the increase in a chip area.

In addition, the semiconductor memory device 1 according to the first embodiment achieves lower amplitude currents in the data bus. A semiconductor memory device according to the comparison example includes a sense amplifier SA and a plurality of latch circuits (SDL, UDL, LDL, and XDL) for a single bit line. Data transfer between the latch circuits is performed through buses LBUS and DBUS. Further, the semiconductor memory device 1 according to the first embodiment includes the latch circuits TDL. The latch circuits TDL are used for data transfer between the sense amplifier module 12 and the data cache 14. The latch circuits TDL and XDL are connected by the bus DXBUS therebetween. When the electrical potential of the data buses (bus LBUS, DBUS, and DXBUS) is set to the power supply voltage VDDSA when data transfer is performed between the latch circuits, a charging or discharging current of the data buses becomes large by the influence of the parasitic capacitances of the data buses.

Here, the electrical potential of the data buses is set to the voltage (Vclh−Vt) which is lower than VDDSA, instead of VDDSA. Therefore, it is possible to reduce the charging or discharging current of the data buses and it is possible to reduce current consumption in the data buses by half to quarter relative to the comparison example.

Further, the electrical potential of the gates of the transfer transistors (transistors 60, 61, 70, 71, 80, and 81 in FIG. 7) of the latch circuits is set to a prescribed voltage (for example, Vclm or Vcll) which is lower than VDDSA. Therefore, it is possible to prevent erroneous operations of the transfer transistors because a voltage for charging the data buses is lowered, and it is possible to improve the operational stability of the latch circuits.

In addition, the semiconductor memory device 1 according to the first embodiment alternately transfers data by dividing the sense amplifier units SAU and the latch circuits XDL into two groups between the sense amplifier module 12 and the data cache 14. When the bus DBUSA and the bus DBUSB are alternately charged, it is possible to reduce the charge amount of the data buses which are necessary when one data is transferred, and thus it is possible to reduce current consumption.

### [2] Second Embodiment

In a semiconductor memory device 1 according to a second embodiment, the memory cell array 10 and the sense amplifier module 12 are formed on the same well, and low voltage-resistant transistors are used for the BL switching circuits 11A and 11B.

[2-1] Configuration

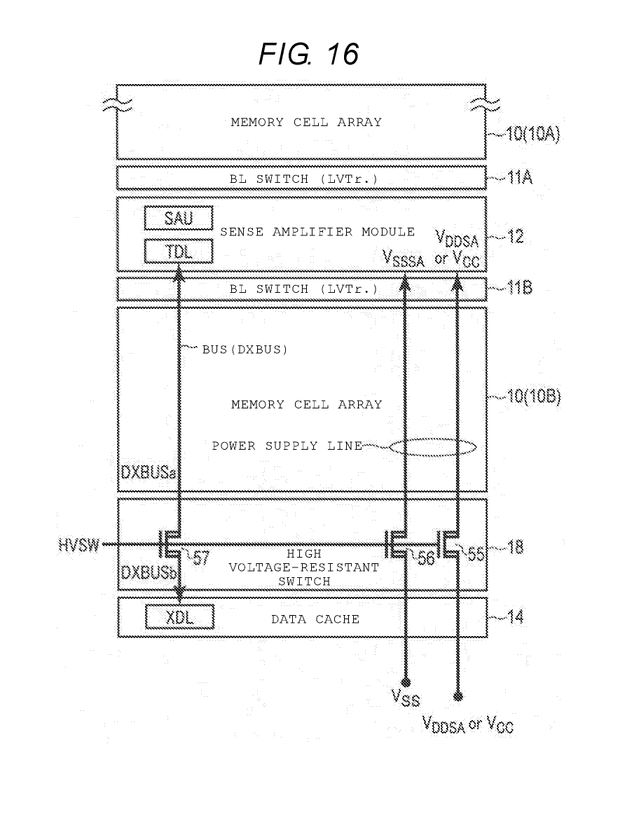

The configuration of the semiconductor memory device 1 according to the second embodiment will be described with reference to FIG. 16. The semiconductor memory device 1 includes the BL switching circuits 11A and 11B which are formed of low voltage-resistant transistors (LVTr.). Further, the semiconductor memory device 1 includes a high voltage-resistant switching circuit 18.

The high voltage-resistant switching circuit 18 is arranged between the memory cell array 10B and the data cache 14, and includes high voltage-resistant n-channel MOS transistors 55 to 57. The transistor 56 includes one end to which a grounding voltage VSS is input, and the other end from which a grounding voltage VSSSA is output. The transistor 55 includes one end to which the power supply voltage VDDSA (or VCC) is input, and the other end from which the power supply voltage VDDSA is output. That is, the transistors 55 and 56 are interposed in the power supply lines which supply power to the BL switching circuits 11A and 11B and the sense amplifier module 12. The transistor 57 includes one end which is connected to the latch circuits XDL, and the other end which is connected to the latch circuits TDL. That is, the transistor 57 is interposed in the middle of the bus DXBUS. With regard to the transistor 57, the bus DXBUS on the side of the latch circuits TDL is expressed as a bus DXBUSa, the bus DXBUS on the side of the latch circuits XDL is expressed as a bus DXBUSb.

A signal HVSW is input to each of the gates of the transistors 55 to 57. The signal HVSW is at the “L” level in the case of a reading or writing operation, and is at the “H” level in the case of an erasing operation. That is, the transistors 55 to 57 are turned on in the case of the reading or writing operation, and turned off in a case of the erasing operation.

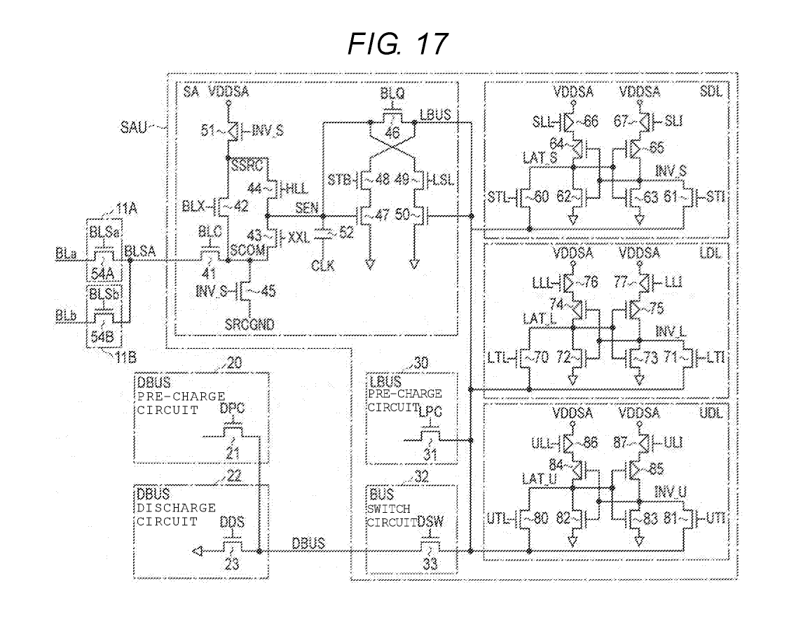

The configurations of the BL switching circuits 11A and 11B will be described with reference to FIG. 17.

The BL switching circuits 11A and 11B include low voltage-resistant p-channel MOS transistors 54A and 54B, respectively. Circuit diagrams of the sense amplifier units SAU and the BL switching circuits 11A and 11B illustrated in FIG. 17 are the same as in FIG. 7 except that the transistors 40A and 40B are replaced by the transistors 54A and 54B.

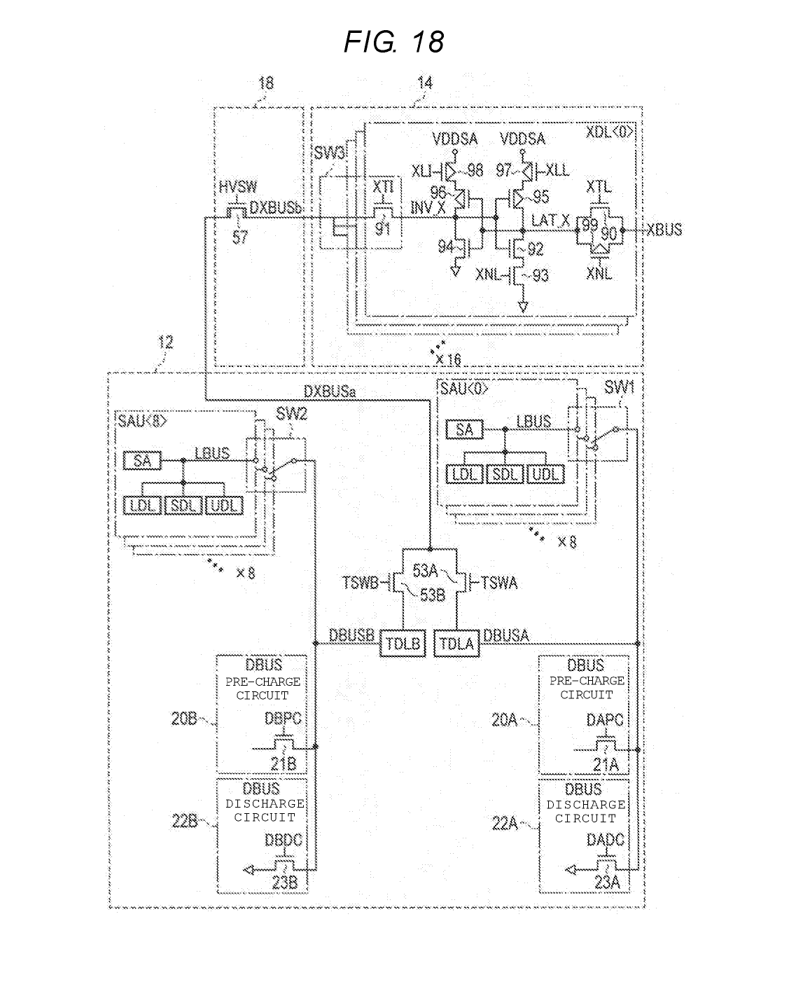

A circuit diagram of the sense amplifier module 12 and the data cache 14, illustrated in FIG. 18, is the same as in FIG. 8 except that the high voltage-resistant switching circuit 18 (transistor 57) is inserted in the wiring of the bus DXBUS. Also, the number of transistors 57 is determined by the number of buses DXBUS in the sense amplifier module 12, and thus the number of necessary high voltage-resistant n-channel transistors (transistors 57) is reduced to one sixteenth of the number of bit lines BL.

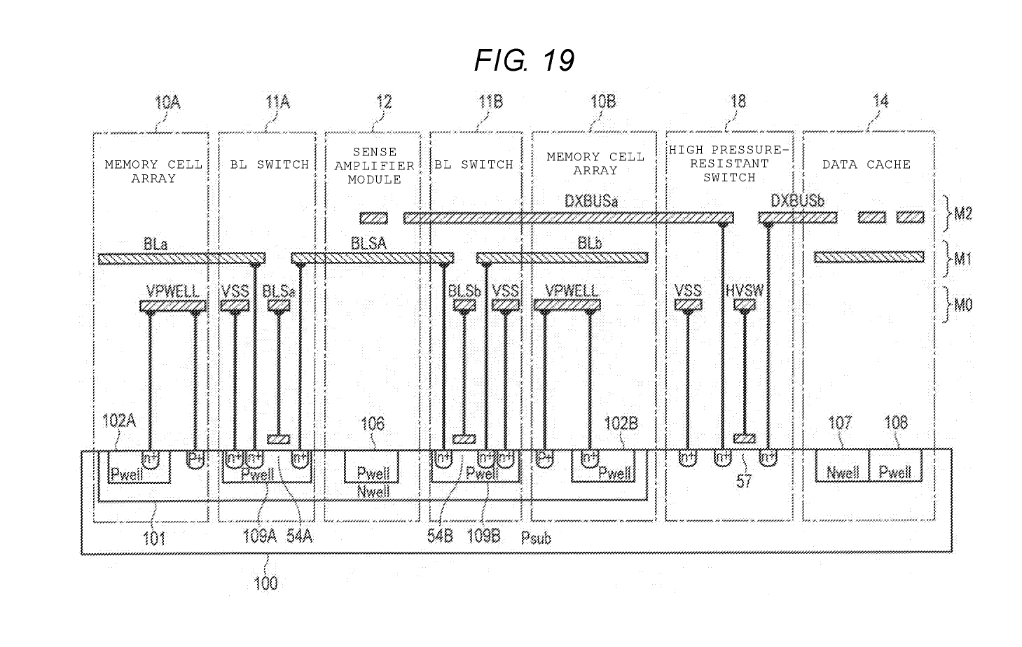

The sectional structure of the semiconductor memory device 1 will be described with reference to FIG. 19. FIG. 19 illustrates the sectional structure which includes the transistor 57 of the high voltage-resistant switching circuit 18.

In the respective areas of the memory cell arrays 10A and 10B, the p-type well areas 102A and 102B are formed on the surface of an n-type well area 101.

In the respective areas of the BL switching circuits 11A and 11B, the p-type well areas 109A and 109B are formed on the surface of the n-type well area 101. The respective transistors 54A and 54B are formed on the surface of the p-type well areas 109A and 109B. The respective gates of the transistors 54A and 54B are connected to the wirings of the layer M0.

In the area of the sense amplifier module 12, the p-type well area 106 is formed on the surface of the n-type well area 101. The n-type well area 105 of the semiconductor memory device 1 according to the first embodiment corresponds to the n-type well area 101.

As described above, the well areas in which the memory cell arrays 10A and 10B, the BL switching circuits 11A and 11B, and the sense amplifier module 12 are formed, are formed on the surface of the same n-type well area 101.

In the area of the high voltage-resistant switching circuit 18, the transistor 57 is formed on the surface of the p-type silicon substrate 100. The transistor 57 includes one end which is connected to the bus DXBUSa, the other end which is connected to the bus DXBUSb, and a gate which is connected to the wiring of the layer M0. In the area of the high voltage-resistant switching circuit 18, the grounding voltage VSS is input. The transistors 55 and 56 have the same configuration as the transistor 57, but include ends that are connected to different wirings.

In the case of the above configuration, an erasing voltage VPWELL is applied to the BL switching circuits 11A and 11B and the circuits of the sense amplifier module 12 in addition to the memory cell arrays 10A and 10B in the case of the erasing operation. When the transistors which are included in the high voltage-resistant switching circuit 18 are turned off, it is possible to cause the BL switching circuits 11A and 11B and the circuits of the sense amplifier module 12 to be floating. Therefore, the BL switching circuits 11A and 11B and the circuits of the sense amplifier module 12 are protected.

Also, the high voltage-resistant switching circuit 18 may be arranged between the memory cell arrays 10A and 10B. In addition, the high voltage-resistant switching circuit 18 may be divided into the transistors 55 and 56 and the transistor 57, and one of the transistors may be arranged between the sense amplifier module 12 and the memory cell array 10B, and the other transistor may be arranged between the memory cell array 10B and the data cache 14. However, when the transistors are arranged as above, electrical potential difference occurs between the bus DXBUS and/or power supply lines and the memory cell array 10B in the case of the erasing operation. Therefore, the wiring capacity of the bus DXBUS and the power supply lines increases in the case of the erasing operation, and thus current consumption increases compared to the disposition of the high voltage-resistant switching circuit 18 of FIG. 16.

In the semiconductor memory device 1 according to the above configuration, when the erasing voltage VPWELL is applied to the n-type well area 101 in the case of the erasing operation, the erasing voltage VPWELL is applied to the BL switching circuits 11A and 11B and the sense amplifier module 12 in addition to the memory cell arrays 10A and 10B. The other operations are the same as in the first embodiment.

[2-2] Advantage of Second Embodiment

In the semiconductor memory device 1 according to the second embodiment, the BL switching circuit 11 includes the low voltage-resistant p-channel transistors 54A and 54B. The length of the gate of the low voltage-resistant n-channel transistor is, for example, 0.3 μm, and the length of the gate of the high voltage-resistant n-channel transistor is, for example, 1.2 μm. That is, when the high voltage-resistant n-channel transistor is replaced by the low voltage-resistant p-channel transistor, the size of the BL switching circuit 11 becomes substantially a quarter.

In the semiconductor memory device 1 according to the second embodiment, the high voltage-resistant switching circuit 18 is added, and a size corresponding to the high voltage-resistant switching circuit 18 increases. However, the number of necessary high voltage-resistant n-channel transistors is equal to the number of buses DXBUS (which is, for example, one sixteenth of the number of bit lines BL), the chip area of the semiconductor memory device 1 according to the second embodiment is smaller than the first area even though there is an increase in the chip area of the high voltage-resistant switching circuit 18.

In addition, in the above configuration, it is possible to acquire the same advantage as in the first embodiment.

### [3] Third Embodiment

In a semiconductor memory device 1 according to a third embodiment, the BL switching circuits 11A and 11B are arranged in an area of the sense amplifier module 12.

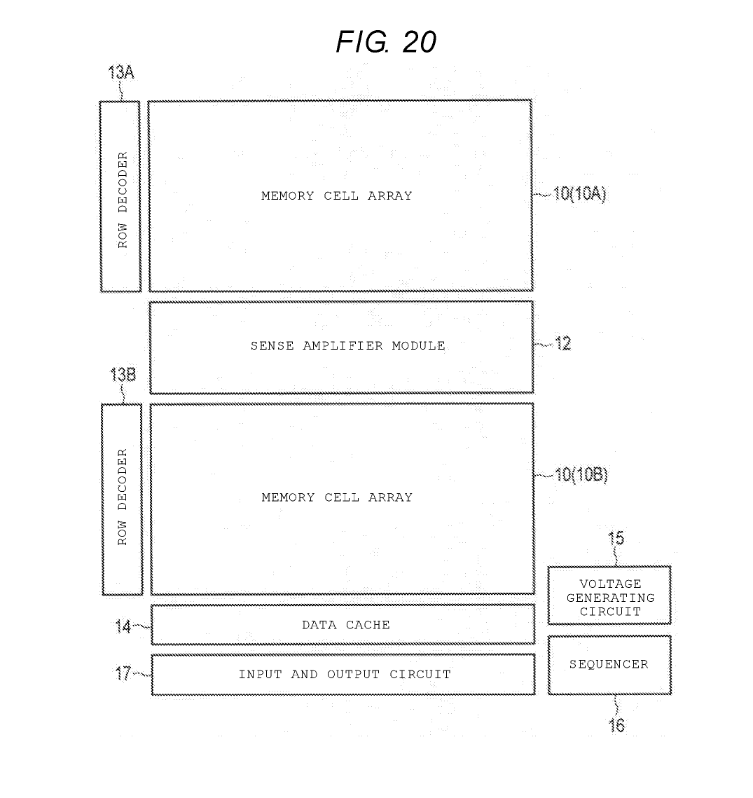

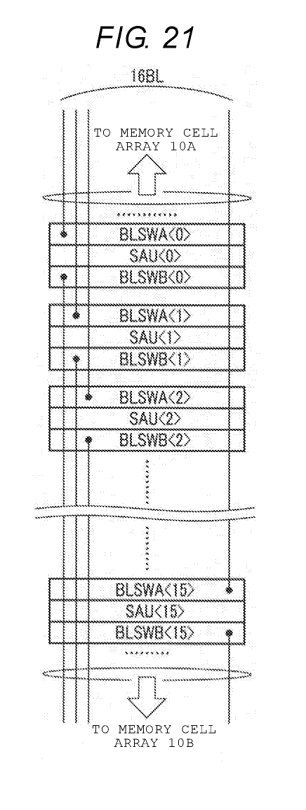

The configuration of the sense amplifier module 12 will be described with reference to FIGS. 20 and 21.

As illustrated in FIG. 20, in the semiconductor memory device 1 according to the third embodiment, the areas of the BL switching circuits 11A and 11B are not separately provided and the BL switching circuits 11A and 11B are arranged in an area in the sense amplifier module 12. The other configurations are the same as in the first embodiment.

FIG. 21 illustrates the disposition of the BL switching circuits 11A and 11B in the area of the sense amplifier module 12, the BL switching circuits 11A and 11B corresponding to the sense amplifier units SAU<15:0> are expressed as BL switching circuits BLSWA<0> to <15> and BLSWB<0> to <15>, respectively.

The respective BL switching circuits 11A and 11B are arranged to be adjacent to the corresponding sense amplifier units SAU. More specifically, the BL switching circuit BLSWA<0> is arranged on the side of the memory cell array 10A of the sense amplifier SAU<0>, and the BL switching circuit BLSWB<0> is arranged on the side of the memory cell array 10B. The connection relationship between the sense amplifier units SAU and the relevant BL switching circuits 11A and 11B is the same as in FIG. 7.

As described above, even when the BL switching circuit 11 is arranged in the area in the sense amplifier module 12, it is possible to acquire the same advantage as in the first embodiment. Also, the disposition of the BL switching circuits 11A and 11B is not limited thereto when the connection relationship between the sense amplifier units SAU and the relevant BL switching circuits 11A and 11B is the same. In addition, it is possible to apply the third embodiment to the second embodiment. In such a case, it is possible to acquire the same advantage as in the second embodiment.

### [4] Fourth Embodiment

A semiconductor memory device 1 according to a fourth embodiment is an application example in which the memory cell array 10 includes a resistance change memory. The resistance change memory uses, for example, memory cells in which a resistance change element, such as a Resistive Random Access Memory (ReRAM), a Phase-Change Random Access Memory (PCRAM), or a Magneto-resistive Random Access Memory (MRAM), is used.

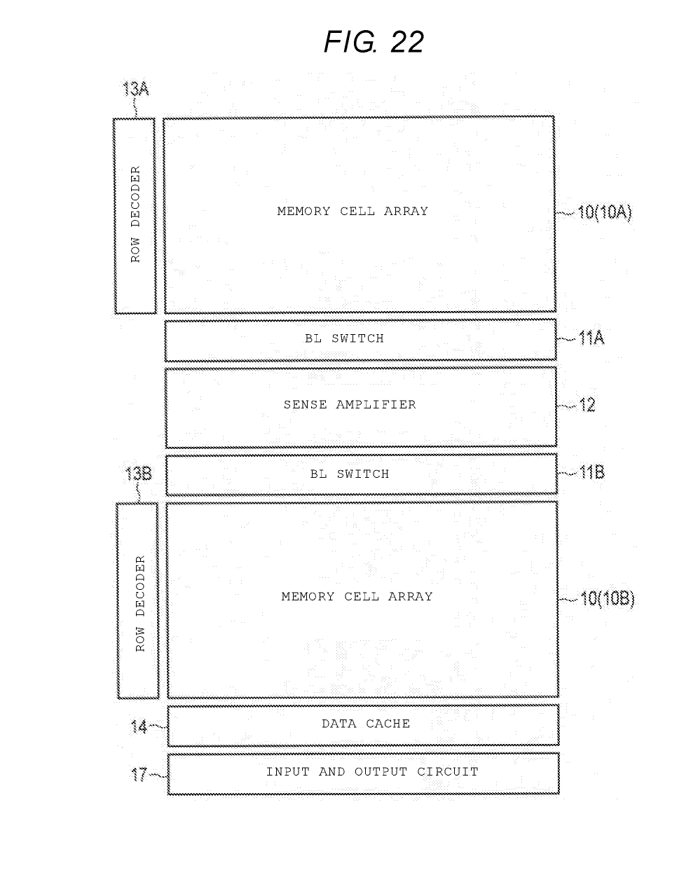

The configuration of the semiconductor memory device 1 according to the fourth embodiment will be described with reference to FIG. 22.

In the memory cell arrays 10A and 10B, memory cells MC, in which the resistance change element, such as the ReRAM, the PCRAM, or the MRAM, is used, are arranged in a matrix configuration. The sense amplifier module 12 is arranged between the memory cell arrays 10A and 10B, and the memory cell arrays 10A and 10B share the sense amplifier module 12.

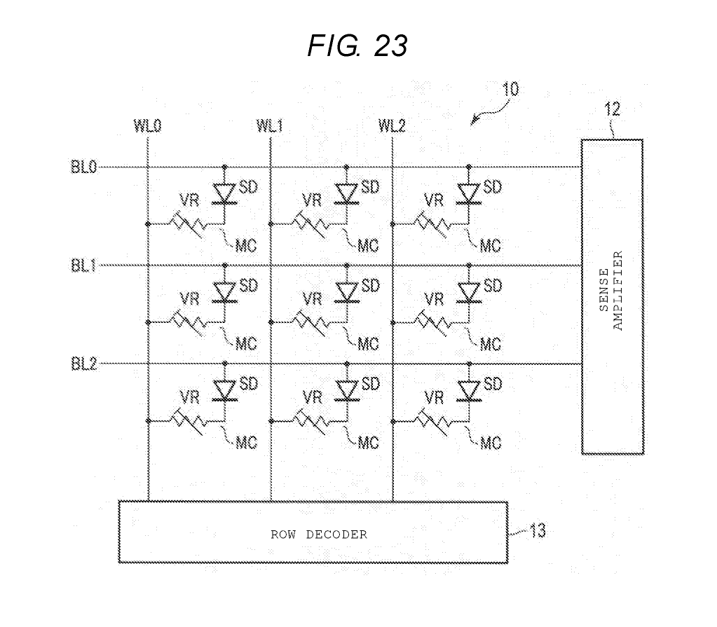

The circuit configuration of the memory cell array 10 will be described with reference to FIG. 23. In the fourth embodiment, the ReRAM will be described as an example.

In the memory cell array 10, for example, three word lines WL0 to WL2 are arranged in parallel. In addition, for example, three bit lines BL0 to BL2 are arranged in parallel and cross the word lines WL. In the respective intersections of the word lines WL and the bit lines BL, the memory cells MC are arranged to be interposed between the both wirings.

The memory cell MC includes a diode SD and a variable resistive element VR which are connected in series. The diode SD is used as a non-ohmic element, and includes an anode which is connected to the bit line BL and a cathode which is connected to the word line WL through the variable resistive element VR. Also, in the diode SD, current may flow from the side of the word line WL to the side of the bit line BL by reversing polarity. The variable resistive element VR may change a resistance value through current, heat, chemical energy, or the like when a voltage is applied.

An operation performed by the memory cell array 10 will now be described.

When data is written into the memory cell MC, for example, a voltage of 4.5 V (actually, substantially 6 V when including the amount of voltage drop of the diode, which is connected to the variable resistive element in series, as a rectifying element) and a current of substantially 10 nA are applied to the variable resistive element for a time of substantially 10 ns to 100 ns (set operation). Therefore, the state of the variable resistive element changes from a high-resistance state to a low-resistance state.

When the data of the memory cell MC is erased, a voltage of 0.7 V (actually, substantially 2.2 V when including the amount of voltage drop of the diode) and a current of substantially 1 μA to 10 μA are applied to the variable resistive element in the low-resistance for a time of substantially 200 ns to 1 μs state (reset operation) after the set operation is performed. Therefore, the state of the variable resistive element changes from the low-resistance state to the high-resistance state.

In the memory cell, for example, the high-resistance state is set as a stable state (the reset state or the erasing state), and the low-resistance state is set as the set state or a program state. When binary data is stored, the data is written by performing the set operation of applying a set pulse to, for example, only a cell desired to be programmed from among the memory cells in the reset state. In the erasing operation, reset pulse is applied regardless of the cell state (the set state or the reset state).

When the data of the memory cell MC is read, a voltage of 0.4 V (actually, substantially 1.9 V when including the amount of voltage drop of the diode) is applied to the variable resistive element, and current which flows through the variable resistive element is monitored. Therefore, the data stored in the variable resistive element is read by determining whether the variable resistive element is in the low-resistance state or in the high-resistance state. Also, the memory cell MC may have a form in which the data of the plurality of memory cells MC connected to a selected word line WL may be read as a unit even when the memory cell MC is individually selected.

As described above, the semiconductor memory device 1 according to the fourth embodiment includes a resistance change memory. In such a resistance change memory using the ReRAM, the PCRAM, the MRAM or the like, it is possible to acquire the advantage which is the same as in the first embodiment. In addition, with regard to the respective second and third embodiments, it is possible to configure the memory cell array 10 using the resistance change memory, and thus it is possible to acquire the same advantage.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

(1) In the reading operation, a voltage, which is applied to a word line selected in the reading operation, at an A level is, for example, in a range of 0 V to 0.55 V. The voltage is not limited thereto, and may be in a range of 0.1 V to 0.24, 0.21 V to 0.31 V, 0.31 V to 0.4 V, 0.4 V to 0.5 V, or 0.5 V to 0.55 V.

A voltage, which is applied to a word line selected in the reading operation, at a B level is, for example, in a range of 1.5 V to 2.3 V. The voltage is not limited thereto, and may be in a range of 1.65 V to 1.8 V, 1.8 V to 1.95 V, 1.95 V to 2.1 V, or 2.1 V to 2.3 V.

A voltage, which is applied to a word line selected in the reading operation, at a C level is, for example, in a range of 3.0 V to 4.0 V. The voltage is not limited thereto, and may be in a range of 3.0 V to 3.2 V, 3.2 V to 3.4 V, 3.4 V to 3.5 V, 3.5 V to 3.6 V, or 3.6 V to 4.0 V.

A time (tR) of the reading operation may be in, for example, a range of 25 μs to 38 μs, 38 μs to 70 μs, or 70 μs to 80 μs.

(2) The writing operation includes a programming operation and a verifying operation as described above. In the writing operation, a voltage, which is initially applied to a word line which is selected when the programming operation is performed, is, for example, in a range of 13.7 V to 14.3 V. The voltage is not limited thereto, and may be, for example, in a range of 13.7 V to 14.0 V or 14.0 V to 14.6 V.

A voltage, which is initially applied to a selected word line when an odd-numbered word line is written, may be changed to a voltage which is initially applied to a selected word line when an even-numbered word line is written.

When the programming operation is performed in an Incremental Step Pulse Program (ISPP) manner, for example, substantially 0.5 V may be an example of a step-up voltage.

A voltage which his applied to a non-selected word line may be, for example, in a range of 6.0 V to 7.3 V. The voltage is not limited to this case and the voltage may be, for example, in a range of 7.3 V to 8.4 V or may be equal to or lower than 6.0 V.

A path voltage to be applied may be changed based on whether the non-selected word line is the odd-numbered word line or the even-numbered word line.

A time (tProg) of the writing operation may be, for example, in a range of 1,700 μs to 1,800 μs, 1,800 μs to 1,900 μs, or 1,900 μs to 2,000 μs.

(3) In the erasing operation, a voltage, which is initially applied to wells which are formed on an upper portion of a semiconductor substrate and above which the memory cells are arranged, is, for example, in a range of 12 V to 13.6 V. The voltage is not limited to this case, for example, in a range of 13.6 V to 14.8 V, 14.8 V to 19.0 V, 19.0 V to 19.8 V, or 19.8 V to 21 V.

A time (tErase) of the erasing operation may be, for example, in a range of 3,000 μs to 4,000 μs, 4,000 μs to 5,000 μs, or 5,000 μs to 9,000 μs.

(4) The structure of the memory cells includes a charge storage layer which is arranged on the semiconductor substrate (silicon substrate) through a tunnel insulation film having a film thickness of between 4 and 10 nm. It is possible for the charge storage layer to have a stacked structure of an insulation film, such as SiN or SiON, which has a film thickness of between 2 and 3 nm, and a poly-silicon which has a film thickness of between 3 and 8 nm. In addition, a metal, such as Ru, may be added to the poly-silicon. The charge storage layer has an insulation film thereon. The insulation film includes, for example, a silicone oxide film having a film thickness of between 4 and 10 nm. The silicone oxide film is interposed between a low layer High-k film having a film thickness of between 3 and 10 nm and a high layer High-k film having a film thickness of between 3 and 10 nm. HfO or the like may be an example of the High-k film. In addition, it is possible to set the film thickness of the silicone oxide film to be greater than the film thickness of the High-k film. A control electrode having a film thickness of between 30 nm and 70 nm is formed on the insulation film through a material having a film thickness of between 3 and 10 nm. The material includes a metal oxide film, such as TaO, or a metal nitride film such as TaN. It is possible to use W or the like as the control electrode.

In addition, it is possible to form an air-gap between the memory cells.

What is claimed is:

1. A semiconductor memory device comprising:
a first memory cell array electrically connected to a set of first bit lines;
a second memory cell array electrically connected to a set of second bit lines; and
a sense amplifier module that is physically located between the first and second memory cell arrays, and shared by the first and second memory cell arrays.

2. The semiconductor memory device according to claim 1, wherein
the sense amplifier module includes sense amplifier units, each of which is connected to a corresponding one of the first bit lines and a corresponding one of the second bit lines.

3. The semiconductor memory device according to claim 2, further comprising:
a first switching circuit connected between the sense amplifier units and the first bit lines, the first switching circuit being controlled to electrically connect and disconnect the sense amplifier units and the first bit lines, and
a second switching circuit connected between the sense amplifier units and the second bit lines, the second switching circuit being controlled to electrically connect and disconnect the sense amplifier units and the second bit lines.

4. The semiconductor memory device according to claim 3,
wherein each of the first and second switching circuits includes high voltage-resistant transistors.

5. The semiconductor memory device according to claim 3,
wherein each of the first and second switching circuits includes low voltage-resistant transistors.

6. The semiconductor memory device according to claim 3, wherein
the first and second memory cell arrays, the sense amplifier module, and the first and second switching circuits are formed on the same well area.

7. The semiconductor memory device according to claim 1, further comprising:
a data cache configured to cache data transmitted from the sense amplifier module to an input/output circuit and to cache data transmitted from the input/output circuit to the sense amplifier module, wherein
the data cache is physically located adjacent to the second memory cell array such that the sense amplifier module and the second memory cell array are between the first memory cell array and the data cache.

8. The semiconductor memory device according to claim 7, wherein the sense amplifier module includes a first latch circuit and the data cache includes a second latch circuit electrically connected to the first latch circuit.

9. The semiconductor memory device according to claim 8, wherein the first latch circuit includes a first latch that is electrically connected to a first set of the sense amplifier units through a first bus and a second latch that is electrically connected to a second set of the sense amplifier units through a second bus.

10. The semiconductor memory device according to claim 9, wherein the sense amplifier module further includes a first pre-charge circuit and a first discharge circuit for the first bus, and a second pre-charge circuit and a second discharge circuit for the second bus.

11. The semiconductor memory device according to claim 7, further comprising:
a switching circuit that is controlled to electrically connect and disconnect the sense amplifier units and the data cache, wherein
the switching circuit includes high voltage-resistant transistors and is physically located between the second memory cell array and the data cache.

12. The semiconductor memory device according to claim 7, further comprising:
a switching circuit that is controlled to electrically connect and disconnect the sense amplifier units and a power supply, wherein
the switching circuit includes high voltage-resistant transistors and is physically located between the second memory cell array and the data cache.

13. The semiconductor memory device according to claim 12, further comprising:
a first wiring that connects the sense amplifier units and the data cache, the first wiring passing over an area of the second memory cell array.

14. The semiconductor memory device according to claim 13, further comprising:
a second wiring that connects the sense amplifier units and the power supply, and the second wiring passing over an area of the second memory cell array.

15. A semiconductor memory device comprising:
first and second memory cell arrays formed on a substrate; and
sense amplifier units for the first and second memory cell arrays formed on the substrate between the first and second memory cell arrays.

16. The semiconductor memory device according to claim 15, further comprising:
a first switching circuit that is controlled to electrically connect and disconnect the first memory cell array and the sense amplifier units, and formed on the substrate between the first memory cell array and the sense amplifier units, and
a second switching circuit that is controlled to electrically connect and disconnect the second memory cell array and the sense amplifier units, and formed on the substrate between the second memory cell array and the sense amplifier units.

17. The semiconductor memory device according to claim 16, further comprising:
a data cache configured to cache data transmitted from the sense amplifier units to an input/output circuit and to cache data transmitted from the input/output circuit to the sense amplifier units, wherein
the data cache is formed on the substrate adjacent to the second memory cell array such that the first and second switching circuits, the sense amplifier units, and the second memory cell array are between the first memory cell array and the data cache.

18. The semiconductor memory device according to claim 17, further comprising:
a first latch that is electrically connected to a first set of the sense amplifier units through a first bus and a second latch that is electrically connected to a second set of the sense amplifier units through a second bus.

19. The semiconductor memory device according to claim 18, wherein the data cache includes a third latch that is electrically connected to both the first and second latches through a third bus.

20. The semiconductor memory device according to claim 19, further comprising a first pre-charge circuit and a first discharge circuit for the first bus, and a second pre-charge circuit and a second discharge circuit for the second bus.
